(19) United States
(12) Patent Application Publication
(10) Pub. No.: US 2026/0359499 A1
(43) Pub. Date: Nov. 12, 2026

(54) WIRELESS CONNECTIVITY-BASED DATA CENTER FLOOR PLANNING

(71) Applicant: MELLANOX TECHNOLOGIES, LTD., Yokneam (IL)

(72) Inventors: Aleksey Dyskin, Haifa (IL); Elad Mentovich, Tel Aviv (IL)

(21) Appl. No.: 19/200,614

(22) Filed: May 6, 2025

(51) Int. Cl. G06F 30/13; H04W 16/20

(52) U.S. Cl. CPC G06F 30/13; H04W 16/20

(57) ABSTRACT

A device and method for optimizing data center floor planning utilizing wireless connectivity is described. A system may include one or more devices that determine a physical layout based on wireless requirements and computing component density. In some aspects, wireless communication pathways are used instead of traditional cable routing constraints to generate optimized floor plans, allowing for more flexible and efficient component placement. In some aspects, wireless communication performance metrics between components are monitored to detect changes exceeding predetermined thresholds, and physical arrangements are dynamically reconfigured to maintain optimal connectivity. By considering wireless propagation characteristics, cooling requirements, and power delivery needs, data centers can scale without additional wired infrastructure, reducing physical constraints while enhancing scalability and adaptability to changing operational requirements.

### FIELD OF THE DISCLOSURE

The present disclosure is generally directed toward data centers and, in particular, toward data center design and methods for generating the same.

### BACKGROUND

Data-center facilities host large numbers of computing components, such as servers, storage nodes, and networking switches, that communicate to deliver cloud, enterprise, and edge services. Conventional installations position these components within rack rows separated by service aisles, with interconnectivity provided predominantly through wired media including copper Ethernet and optical fiber. The arrangement of components is influenced by cable-routing paths, patch-panel locations, and under-floor or overhead tray architectures, while cooling design often relies on hot-aisle/cold-aisle patterns to maintain acceptable operating temperatures. As workloads scale and diversify, operators may evaluate approaches for increasing component density, reducing latency, and improving energy efficiency. Efforts in this area include optimizing rack power distribution, refining airflow management, and introducing software-defined management of network resources.

### GENERAL DESCRIPTION

Aspects of the present disclosure are directed to systems, apparatuses, and computer-implemented methods that generate and apply wireless-aware floor plans for data-center computing components. In some aspects, a planning engine may ingest component metadata (e.g., physical dimensions, wireless transceiver capabilities) together with layout constraints such as thermal limits, workload affinities, and target signal-quality thresholds. Using an optimization solver or, in some aspects, a trained machine-learning model, the planning engine predicts spatial coordinates for each component and supplies corresponding wireless configuration parameters that may include, but are not limited to, wireless channel assignments, antenna orientations, power states, and cooling setpoints. The resulting floor plan may then be deployed through an orchestration interface that provides the wireless configuration parameters to the components and, in some instances, revises placements in response to real-time telemetry or environmental changes. By treating received-signal strength, interference contours, and bandwidth availability as primary placement variables, aspects described herein provide a flexible, scalable rearrangement of racks, trays, pods, switches, or other compute elements without reliance on fixed cable routing infrastructure.

Example aspects of the present disclosure provide an apparatus. The apparatus may comprise one or more memory devices to store data describing a plurality of computing components and one or more wireless connectivity requirements for a data center; and one or more processors, coupled to the one or more memory devices, to: determine a physical layout for the plurality of computing components based at least on the one or more wireless connectivity requirements and a computing component density within the data center; and generate a floor plan for the data center based on the physical layout.

Aspects include wherein the plurality of computing components comprises at least one of a server, a tray, a rack, a pod, or a cluster.

Aspects include wherein the physical layout is determined based on a wireless connectivity architecture independent of cable routing paths.

Aspects include wherein the one or more processors are further to: obtain a measure of wireless communication parameter between the plurality of computing components; and determine a placement of one or more computing components of the plurality of computing components based on the measure of the wireless communication parameter.

Aspects include wherein the one or more processors are further to: position the plurality of computing components within the floor plan based on a threshold associated with a wireless communication parameter for one or more communicating components of the plurality of computing components.

Aspects include wherein the threshold associated with the wireless communication parameter includes at least one wireless propagation characteristic comprising at least one of: signal frequency, bandwidth, modulation scheme, signal strength, data rate, latency, bit error rate, or signal interference.

Aspects include wherein the one or more processors are further to: adjust the physical layout based on a cooling requirement of one or more computing components of the plurality of computing components within the data center.

Aspects include wherein the one or more processors are further to: modify the physical layout based on a power delivery requirement of one or more computing components of the plurality of computing components within the data center.

Aspects include wherein the floor plan indicates positions of the plurality of computing components and corresponding wireless connectivity paths between the plurality of computing components.

Aspects include wherein the one or more processors are further to: transmit a configuration to at least one wireless communication device to configure a wireless connectivity path between a pair of computing components of the plurality of computing components.

Aspects include wherein the one or more processors are further to: reconfigure physical positions of one or more computing components of the plurality of computing components in response to changes in wireless communication performance.

Aspects include wherein the one or more processors are further to: input data describing the plurality of computing components within the data center and the one or more wireless connectivity requirements into a machine-learning model trained to generate data center floor plans, and obtain, from the machine-learning model, the floor plan for the data center.

Aspects include wherein the one or more processors are further configured to dynamically adjust the physical layout to scale a number of computing components within the data center based on at least one of a modified computing requirements or modified wireless connectivity requirements, without adding wired infrastructure.

Aspects include wherein the one or more processors are further configured to determine and configure wireless connectivity paths in response to at least one of an incremental increase or incremental decrease in a number of computing components.

Example aspects of the present disclosure provide a machine-readable medium. In some aspects the machine-readable medium may have data stored thereon, which when executed by one or more processors, cause the one or more processors to: receive data describing a plurality of computing components and one or more wireless connectivity requirements for a data center; determine a physical layout for the plurality of computing components based at least on the one or more wireless connectivity requirements and a computing component density within the data center; and generate a floor plan for the data center based on the physical layout.

Aspects include wherein the plurality of computing components comprises at least one of a server, a tray, a rack, a pod, or a cluster.

Aspects include wherein the physical layout is determined based on a wireless connectivity architecture independent of cable routing paths.

Aspects include wherein the one or more processors are to: adjust the physical layout based on a cooling requirement of one or more computing components of the plurality of computing components within the data center and a power delivery requirement of one or more computing components of the plurality of computing components within the data center.

Example aspects of the present disclosure provide an apparatus. In some aspects, the apparatus may comprise one or more memory devices to store a wireless communication performance threshold; and one or more processors, coupled to the one or more memory devices, to: monitor wireless communication performance metrics between a plurality of computing components within a data center arranged according to an initial floor plan; detect a change in at least one of the wireless communication performance metrics that exceeds the wireless communication performance threshold; identify one or more computing components associated with the detected change; and determine a modified physical arrangement for the identified one or more computing components based on the wireless communication performance metrics.

Aspects include wherein the wireless communication performance metrics comprise at least one of signal strength, data throughput, latency, bit error rate, packet loss, signal-to-noise ratio, or channel quality indicator.

Aspects include wherein the one or more processors are to: generate instructions for physically relocating the identified one or more computing components according to the modified physical arrangement; and transmit the instructions to a data center management system for implementation.

Aspects include wherein the one or more processors are to: determine a temporary wireless communication path to maintain network connectivity during physical relocation of the identified one or more computing components; configure one or more wireless communication devices to implement the temporary wireless communication path; and after physical relocation of the identified one or more computing components, configure the one or more wireless communication devices to implement a permanent wireless communication path according to the modified physical arrangement.

Additional features and advantages are described herein and will be apparent from the following Detailed Description and the figures.

### BRIEF DESCRIPTION OF THE SEVERAL VIEWS OF THE DRAWINGS

The present disclosure is described in conjunction with the appended figures, which are not necessarily drawn to scale:

FIG. 1 illustrates an example system architecture for generating a wireless-optimized data center layout and associated component configuration parameters, in accordance with aspects of the present disclosure;

FIG. 2 illustrates an example layout space and wireless signal mapping between computing components to guide placement based on wireless performance metrics, in accordance with aspects of the present disclosure;

FIGS. 3A and 3B illustrate, respectively, a traditional grid-based layout constrained by physical wiring, and a wireless-optimized layout with flexible component placement and wireless interconnections, in accordance with aspects of the present disclosure;

FIG. 4A illustrates a system for training a machine-learning model using component data, layout constraints, and performance metrics to generate predictive layout models, in accordance with aspects of the present disclosure;

FIG. 4B illustrates an inference-time deployment of a trained machine-learning model to generate component layouts and operational parameters based on real-time or preprocessed input data, in accordance with aspects of the present disclosure;

FIG. 4C depicts an example processing system with which aspects of the present disclosure can be performed;

FIG. 5 illustrates an example method for generating and applying a wireless-aware floor plan and component configuration parameters in a data center environment, in accordance with aspects of the present disclosure;

FIG. 6A depicts a flowchart of an exemplary method in accordance with at least one aspect of the present disclosure;

FIG. 6B depicts a flowchart of an exemplary method in accordance with at least one aspect of the present disclosure;

FIG. 7 illustrates a block diagram of a system that includes switching circuitry positioned between first and second sets of devices, in accordance with at least one embodiment;

FIG. 8 illustrates a block diagram of an example system, in accordance with at least one embodiment; and

FIG. 9 illustrates an example data center, in accordance with at least one embodiment.

Like reference numbers and designations in the various drawings indicate like elements.

### DETAILED DESCRIPTION

The ensuing description provides embodiments only, and is not intended to limit the scope, applicability, or configuration of the claims. Rather, the ensuing description will provide those skilled in the art with an enabling description for implementing the described embodiments. It is understood that various changes may be made in the function and arrangement of elements without departing from the spirit and scope of the appended claims.

It will be appreciated from the following description, and for reasons of computational efficiency, that the components of the system can be arranged at any appropriate location within a distributed network of components without impacting the operation of the system.

Furthermore, it should be appreciated that the various links connecting the elements can be wired, traces, or wireless links, or any appropriate combination thereof, or any other appropriate known or later developed element(s) that is capable of supplying and/or communicating data to and from the connected elements. Transmission media used as links, for example, can be any appropriate carrier for electrical signals, including coaxial cables, copper wire and fiber optics, electrical traces on a printed circuit board (PCB), or the like.

The term “automatic” and variations thereof, as used herein, refers to any appropriate process or operation done without material human input when the process or operation is performed. However, a process or operation can be automatic, even though performance of the process or operation uses material or immaterial human input, if the input is received before performance of the process or operation. Human input is deemed to be material if such input influences how the process or operation will be performed. Human input that consents to the performance of the process or operation is not to be deemed “material.”

The terms “determine,” “calculate,” and “compute,” and variations thereof, as used herein, are used interchangeably, and include any appropriate type of methodology, process, operation, or technique.

Various aspects of the present disclosure will be described herein with reference to drawings that are schematic illustrations of idealized configurations. Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art.

As modern data centers grow in scale and complexity, physical cabling and static connectivity requirements can limit layout flexibility, impede cooling efficiency, and constrain future expansion. Traditional data center planning often positions racks, servers, and network components based on cable routing paths and port availability, creating costly overhead when adding or relocating components. To address these challenges, aspects of the present disclosure are directed at leveraging wireless connectivity in data center floor planning. In some aspects, a planning engine obtains wireless connectivity requirements, such as signal strength, interference thresholds, and latency targets. The planning engine may use the wireless connectivity requirements to determine an initial physical layout of one or more components. Rather than running fiber or copper cables between nodes, the planning engine may analyze wireless propagation characteristics to position components where wireless signals can be reliably maintained. By reducing the reliance on cable routing, expansions or reconfigurations become more straightforward and cost-effective.

Aspects of the present disclosure are directed to apparatuses, methods, processing systems, and computer-readable mediums for optimizing data center floor planning using wireless connectivity to enhance flexibility, scalability, and performance of computing infrastructure.

Traditional data centers rely on physical cables for interconnecting computing components, creating rigid infrastructure, constraining layout options, and complicating expansion. Aspects of the present disclosure introduce a systematic approach that leverages wireless connectivity as a primary design consideration for data center floor planning. This approach determines an optimal physical placement of computing components such as servers, racks, switches, and pods based on wireless performance parameters, enabling more flexible arrangements not limited by cable routing paths. Aspects of the present disclosure describe a system that can operate proactively during initial planning phases or reactively to adjust component positioning in response to detected performance changes.

Several technical challenges complicate effective data center design. For example, determining an optimal physical placement of computing components while accounting for wireless signal propagation characteristics that vary across physical space presents increased computational complexity. As another example, balancing competing objectives, including wireless performance, thermal efficiency, power delivery, and space utilization, requires sophisticated multi-parameter optimization.

Aspects of the present disclosure are directed to a layout engine that may process component specifications and wireless connectivity requirements to determine spatial arrangements that provide improved signal quality while satisfying component density objectives. Aspects of the disclosure are directed to a system that employs simulation models or trained machine-learning algorithms to predict wireless performance across candidate layouts, avoiding computation-intensive physical testing. In some aspects, a monitoring system may evaluate signal quality metrics against stored thresholds and identify components requiring repositioning when performance degrades. In some aspects, orchestration capabilities may be utilized to maintain temporary communication paths during physical reconfiguration, ensuring network continuity throughout adaptation processes.

In some aspects, by eliminating the dependency on fixed cable routing, aspects described herein may provide efficient use of physical space, potentially increasing computing density compared to traditional layouts. The wireless-first design facilitates incremental scaling without proportional infrastructure costs, as new components can be added without additional cabling or routing hardware. In some aspects, real-time performance monitoring and adaptive reconfiguration improve system resilience and may compensate for environmental changes or component failures that would otherwise require manual intervention. Machine-learning optimization capabilities may improve layout quality over time as the system accumulates performance data across different configurations, enabling continuous refinement rather than requiring periodic redesigns.

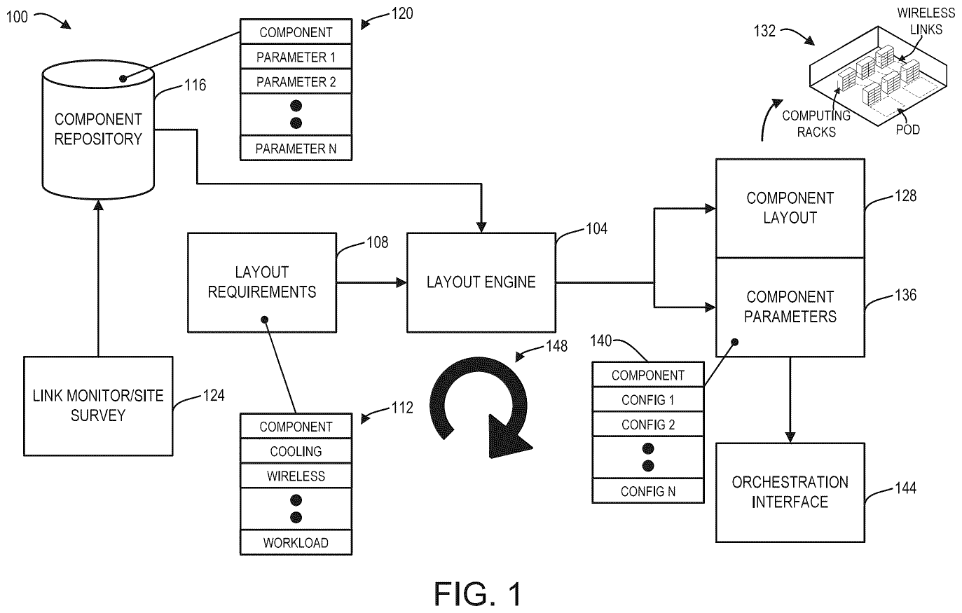

Referring now to FIG. 1, an example system 100 for generating a wireless-optimized physical layout of computing components within a data center is depicted in accordance with aspects of the present disclosure. The system 100 may be implemented in whole or in part via hardware, software, firmware, or any combination thereof. The system 100 may operate locally within a data center or be deployed remotely via a networked architecture.

In some aspects, system 100 may comprise a layout engine 104 that receives input data from one or more sources and generates a proposed component layout 128 and associated component parameters 136 as output. In some aspects, the layout engine 104 may be configured to apply algorithmic or model-based optimization techniques based on physical, thermal, connectivity, and/or workload-related constraints. In some implementations, the layout engine 104 is implemented as a deterministic software routine; in other implementations, the layout engine 104 may invoke a trained machine-learning model and/or utilize reinforcement learning logic, as further described in connection with subsequent figures.

In some aspects, the layout engine 104 may receive input data from layout requirements 108, which includes requirements and constraints that may govern floorplan generation. The layout requirements 108 may encapsulate thermal thresholds, workload clustering requirements, electromagnetic interference tolerances, and wireless connectivity criteria. As depicted in FIG. 1, the layout requirements may include structured data such as those described and shown at 112. Details of the layout requirements, as shown at 112, may represent one or more parameters associated with a computing component, such as “cooling,” “wireless,” and “workload.” Each parameter may be encoded with quantitative metrics (e.g., maximum temperature per unit, acceptable signal-to-noise ratios, latency bounds, or target workload colocation levels) and may be prioritized or weighted according to operational priorities.

The layout engine 104 may access component data via a component repository 116, including metadata or specification profiles for a plurality of computing components. Components may include servers, trays, racks, switches, pods, or other modular computing elements. In some aspects, the repository 116 may be implemented using a local relational database, a distributed object store, and/or a network-accessible configuration management system. Information for a component in the component repository 116 may include static or dynamic attributes of each component, such as physical dimensions, power requirements, radio transceiver characteristics, antenna placement, cooling efficiency profiles, and/or supported communication protocols.

As depicted in FIG. 1, the component repository 116 provides access to component metadata 120, which may include tabular or structured representations of configuration values associated with each component. That is, each component may be associated with a set of parameters (e.g., Parameter 1 through Parameter N), which may include radio channel configuration, frequency bands, maximum supported data rates, error correction capabilities, physical orientation constraints, or airflow considerations. In some aspects, the component repository 116 may be updated dynamically based on telemetry received from deployed hardware, vendor updates, or sensor-derived metrics.

The system 100 may include a link monitor and/or site survey module 124, which may provide additional data to the layout engine 104. The link monitor and/or site survey module 124 may detect, measure, or simulate physical or environmental conditions within a data center. For example, the link monitor and/or site survey module 124 may perform a wireless signal survey to detect ambient signal strengths, interference zones, channel availability, or dead zones. Alternatively or, in addition, the link monitor and/or site survey module 124 may receive telemetry from deployed components, such as link throughput, RSSI levels, bit error rates, or latency measurements. The data provided by the link monitor and/or site survey module 124 may be used to generate or update the layout requirements 108, and may enable iterative optimization or real-time reconfiguration in some implementations.

In some aspects, the output of layout engine 104 includes a component layout 128, which represents a proposed physical placement of components within the data center. The component layout 128 may be encoded in spatial coordinates, rack/pod assignments, or a grid-based representation. The component layout 128 may be visualized using one or more rack diagrams 132, which depicts a physical instantiation of computing racks and associated wireless links within a modular arrangement. As shown, multiple “pods” may be grouped within physical rows or wireless connectivity zones to optimize signal propagation and minimize interference.

In addition to the spatial layout, the layout engine 104 may generate component parameters 136, which may include operational configuration values for one or more of the computing components. Some component parameters 136 may be directed to wireless implementations and indicate the radio frequency assignments, bandwidth allocations, link modulation schemes, antenna beam directions, power levels, and/or cooling setpoints for individual or grouped components. Some component parameters may be directed to configuration settings other than wireless implementation settings. In some aspects, component parameters 136 may be computed based on performance modeling, constraints expressed in the layout requirements 108, and component metadata 120.

Component configuration information 140 depicts additional detail for configuration parameters that represent the component parameters 136 for a specific component. For example, a set of component parameters represented by configuration information 140 may include a component identifier and one or more configurable parameters or settings, such as the radio frequency assignments, bandwidth allocations, link modulation schemes, antenna beam directions, power levels, and/or cooling setpoints for individual or grouped components.

In some aspects, an orchestration interface 144 may be coupled to the layout engine 104 and configured to receive layout and configuration outputs for implementation. In some aspects, the orchestration interface 144 may communicate with infrastructure management software, robotic placement systems, or configuration controllers to physically or logically deploy the proposed layout and configuration parameters. In some aspects, the orchestration interface 144 may communicate directly with one or more components to provide component-specific component parameters 136. A feedback loop 148 symbolically represents an iterative refinement process in which output layouts may be evaluated against performance objectives and revised based on new telemetry, updated constraints, or model inferences. The feedback loop 148 may be implemented via closed-loop control logic, a machine-learning update cycle, or manual revision triggers based on user interaction or system alerts.

In some aspects, the layout engine 104 may incorporate multiple optimization objectives. For instance, layout engine 104 may balance wireless signal quality with thermal considerations, verifying that components are positioned to maintain acceptable operating temperatures while achieving target wireless performance metrics. The layout engine 104 may employ constraint satisfaction algorithms, linear programming techniques, genetic algorithms, or neural network-based approaches to identify layouts that satisfy multiple, potentially competing objectives.

The component repository 116 may maintain versioned configuration profiles, enabling the system to track changes over time and revert to previous configurations if needed. The component repository 116 may also include compatibility matrices that indicate which components can effectively communicate with one another using specific wireless protocols or frequency bands. This information can be utilized by the layout engine 104 to ensure that components placed in proximity to one another can establish viable wireless connections without requiring protocol translation or frequency conversion.

The one or more rack diagrams 132 may be rendered in two-dimensional or three-dimensional formats and may include visual indicators of wireless signal strength, potential interference zones, or cooling airflow patterns. These visualizations can assist operators in understanding the rationale behind the proposed layout and identifying potential areas for manual adjustment or refinement. The orchestration interface 144 may include both manual and automated implementation pathways. For manual implementation, the interface may generate human-readable instructions or visual guides for data center personnel. For automated implementation, the interface may transmit configuration commands directly to programmable network interfaces, wireless controllers, or robotic positioning systems.

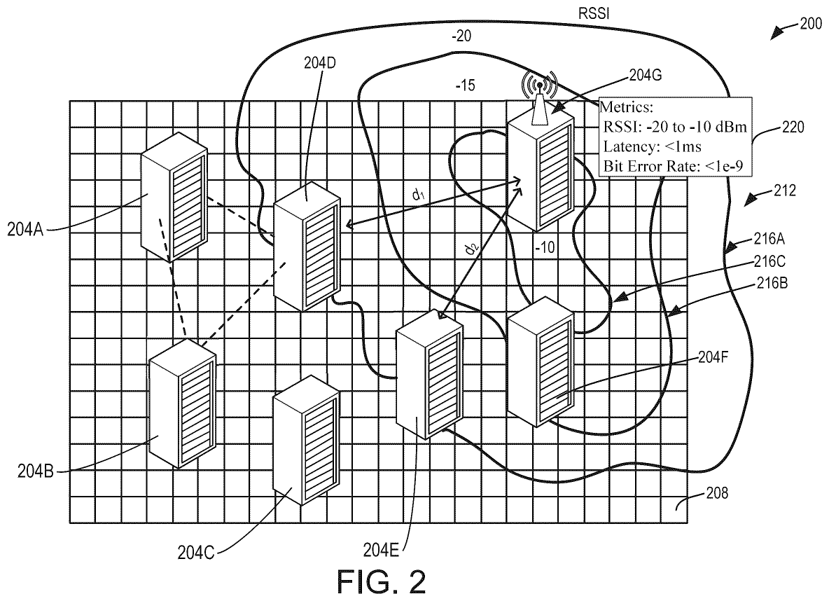

Referring now to FIG. 2, an exemplary layout evaluation environment 200 is illustrated for analyzing and optimizing wireless communication characteristics between computing components in a data center in accordance with aspects of the present disclosure. The environment 200 represents a spatial arrangement wherein a plurality of computing components are positioned to facilitate wireless connectivity-based data center operations, which may be used by the system described in relation to FIG. 1 for floor planning optimization.

The environment 200 comprises a plurality of computing components 204A-204G arranged within a defined spatial grid 208. Each computing component 204A-204G may represent various computing infrastructure elements, including but not limited to servers, trays, racks, pods, switches, or clusters. These components may be positioned according to wireless connectivity requirements rather than traditional cable-routing constraints. The computing components 204A-204G may include embedded wireless communication interfaces or attached wireless transceivers configured to establish wireless connectivity paths between components. In some aspects, the computing components may house processing units, memory elements, storage devices, or other computational resources that may depend on network connectivity for operational functionality.

The component 204G is specifically illustrated with an antenna symbol, indicating that this particular component is functioning as a wireless transmission source in the depicted configuration. Component 204G may serve as a reference transmitter for evaluating signal propagation characteristics throughout the environment 200, or may represent an active node in the operational wireless network. The wireless transmission capabilities may include various technologies such as millimeter wave, sub-terahertz, or terahertz frequency communications as appropriate for high-bandwidth, low-latency data center applications. In some implementations, component 204G may utilize beamforming techniques, directional antennas, or omnidirectional transmission patterns based on configured wireless parameters.

The grid 208 provides a structured spatial reference framework for positioning the computing components 204A-204G. This grid 208 may represent actual floor tiles within a data center, conceptual positioning zones, or computational divisions used by the layout engine during floor plan generation. The grid structure facilitates evaluation of different component arrangements based on wireless communication parameters and physical constraints. In some aspects, the grid structure may be non-uniform, with varying cell sizes to accommodate different densities of computing components or specialized zones within the data center environment.

Overlaid on the grid 208 is a wireless signal mapping 212, which provides visualization of wireless communication characteristics throughout the environment. The wireless signal mapping 212 represents a spatial propagation model indicating how wireless signals emanate from the transmitting component 204G and propagate throughout the environment. This mapping may be derived from actual measurements within an existing data center, from theoretical propagation models, or from a combination of empirical data and computational simulations. The signal mapping enables the layout engine (e.g., layout engine 104 of FIG. 1) to identify optimal positioning of components based on wireless performance metrics rather than physical cable routing paths.

The contour lines 216A, 216B, and 216C represent boundaries of equal wireless signal parameters within the signal mapping 212. For example, contour line 216A may represent a boundary where the received signal strength indicator (RSSI) equals −20 dBm, contour line 216B may represent a boundary where RSSI equals −15 dBm, and contour line 216C may represent a boundary where RSSI equals −10 dBm. These contour lines enable visualization of signal strength gradients throughout the environment, allowing the layout engine (e.g., layout engine 104 of FIG. 1) to position computing components within zones that maintain specified wireless communication parameters. The contour lines may be derived from actual signal measurements, computational electromagnetic simulations, or predictive models trained on historical data.

The environment 200 further indicates relative distances d1, d2, and d3 between the transmitting component 204G and receiving components 204A, 204C, and 204F, respectively. These distances represent spatial separations that influence wireless communication parameters such as signal strength, latency, and bit error rate. The layout engine (e.g., layout engine 104 of FIG. 1) may utilize these distance measurements when determining component placement to ensure wireless connectivity requirements are satisfied in additional to proximity requirements, if any. In some aspects, the distances may be weighted based on environmental factors such as obstructions, reflective surfaces, or other elements that impact wireless propagation.

A metrics callout 220 indicates wireless performance parameters relevant to the environment 200. As shown, the metrics include an RSSI range of −20 to −10 dBm, latency less than 1 millisecond, and bit error rate less than 1×10 \hat{ }−9. These metrics represent target thresholds or measured values that guide component placement decisions. The layout engine (e.g., layout engine 104 of FIG. 1) may utilize these metrics as constraints or optimization targets when generating floor plans. The metrics may vary based on specific workload requirements, computing component specifications, or operational priorities within the data center.

In some aspects, the wireless performance metrics of the metrics call out 220 may be used to evaluate whether a particular layout satisfies connectivity requirements for the data center. For instance, the layout engine (e.g., layout engine 104 of FIG. 1) may position components such that each maintains RSSI values within the specified range to ensure reliable wireless connectivity. Similarly, the latency threshold of less than 1 millisecond may guide placement decisions to ensure that communicating components maintain adequate proximity for time-sensitive applications. The bit error rate threshold ensures data integrity across wireless links, where data corruption could impact computational results or service availability.

In some aspects, the environment 200 may represent a dynamic system wherein computing component positions are adjusted in real-time or periodically based on monitored wireless communication performance. The signal mapping 212 and associated contour lines 216A-216C may be updated continuously or at specified intervals to reflect current conditions within the data center environment.

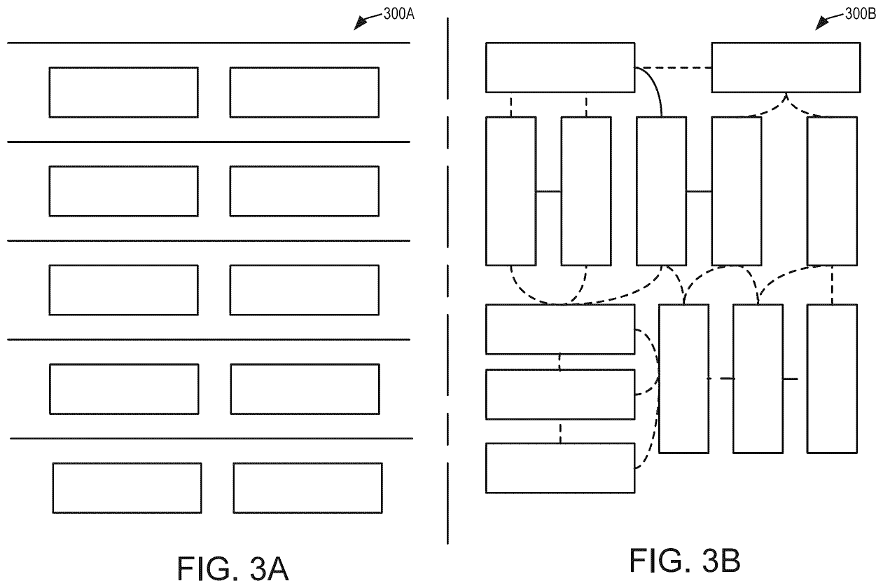

Referring now to FIGS. 3A and 3B, comparative illustrations of data center layouts are shown that demonstrate the contrast between traditional cable-based configurations and wireless-optimized arrangements in accordance with aspects of the present disclosure.

FIG. 3A depicts a conventional data center layout 300A characterized by a regular, grid-like arrangement of computing components. In this traditional configuration, a plurality of computing components are arranged in a structured pattern with uniform spacing between rows. The computing components, represented as rectangular blocks, may correspond to various data center elements such as server racks, trays, chassis, switches, or pods. Each rectangular block represents one or more physical computing resources having specified dimensions, power requirements, and communication interfaces.

The alignment depicted in layout 300A reflects standardized infrastructure design practices, where rows of components may be positioned in parallel and separated by fixed-width aisles. The aisles may serve multiple purposes, including accommodating cable routing pathways, satisfying airflow requirements for thermal management, and providing access corridors for maintenance personnel. The layout 300A facilitates straightforward installation procedures and predictable expansion planning but inherently constrains component placement options due to the physical limitations imposed by cable connections.

In the conventional layout 300A, the positioning of computing components may be influenced by cable routing considerations, including maximum cable length limitations, bend radius restrictions, and physical space requirements for cable management infrastructure. Such constraints may limit optimization opportunities for other operational factors such as cooling efficiency, power distribution, or component density. The arrangement shown in layout 300A may necessitate extensive under-floor or overhead cable management systems that occupy space within the data center facility and potentially create airflow obstructions that impact thermal performance.

In contrast, FIG. 3B illustrates a wireless-optimized data center layout 300B in accordance with aspects of the present disclosure. In this configuration, computing components are arranged in a non-uniform, adaptive pattern that prioritizes wireless communication performance rather than cable routing requirements. The computing components, again represented as rectangular blocks, are positioned according to wireless connectivity parameters and operational requirements rather than constrained by physical interconnect pathways.

Layout 300B features multiple wireless communication links, indicated by dashed lines, that connect various computing components. These wireless links represent bidirectional communication pathways established between transmitting and receiving interfaces on the respective components. The dashed lines visualize logical connectivity that may be implemented using various wireless technologies, potentially including millimeter wave, sub-terahertz, or terahertz frequency communications suitable for high-bandwidth, low-latency data center applications.

The wireless links depicted in layout 300B may be characterized by specific performance metrics such as signal strength, bandwidth capacity, latency, or bit error rate. In some aspects, the positioning of components and establishment of wireless links may be dynamically determined by a layout engine (such as layout engine 104 described in relation to FIG. 1) that accounts for signal propagation characteristics throughout the physical environment.

The absence of physical cabling constraints in layout 300B enables more flexible and efficient use of available floor space. Components may be clustered based on communication affinity, workload requirements, or thermal considerations rather than cable routing paths. For example, components with frequent data exchanges may be positioned to optimize wireless signal quality, while components generating significant heat may be arranged to enhance cooling efficiency.

The non-uniform arrangement in layout 300B may result from a layout optimization process that considers multiple parameters simultaneously, including but not limited to wireless signal strength contours (as described in relation to FIG. 2), interference zones, cooling airflow patterns, power delivery requirements, and computing component density. This multi-objective optimization approach enables data center operators to achieve improved resource utilization and operational efficiency compared to cable-constrained designs.

In some aspects, the wireless-optimized layout 300B may adapt to changing conditions within the data center environment. For instance, if wireless communication performance metrics exceed predetermined thresholds, the physical arrangement of components may be reconfigured to restore optimal connectivity. This adaptability enables responsive scaling of computing resources without the need to install additional cabling infrastructure.

The wireless links shown in layout 300B may be established using directional antennas, beamforming techniques, or omnidirectional transmission approaches depending on specific communication requirements and environmental conditions. In some implementations, wireless connectivity may be complemented by wired connections in a hybrid approach that leverages the advantages of both communication mediums for different types of data traffic or redundancy purposes.

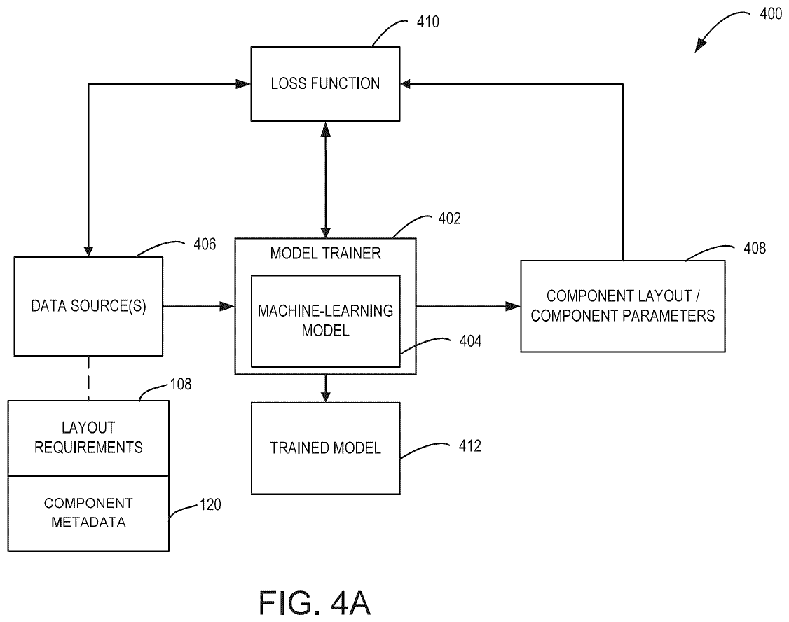

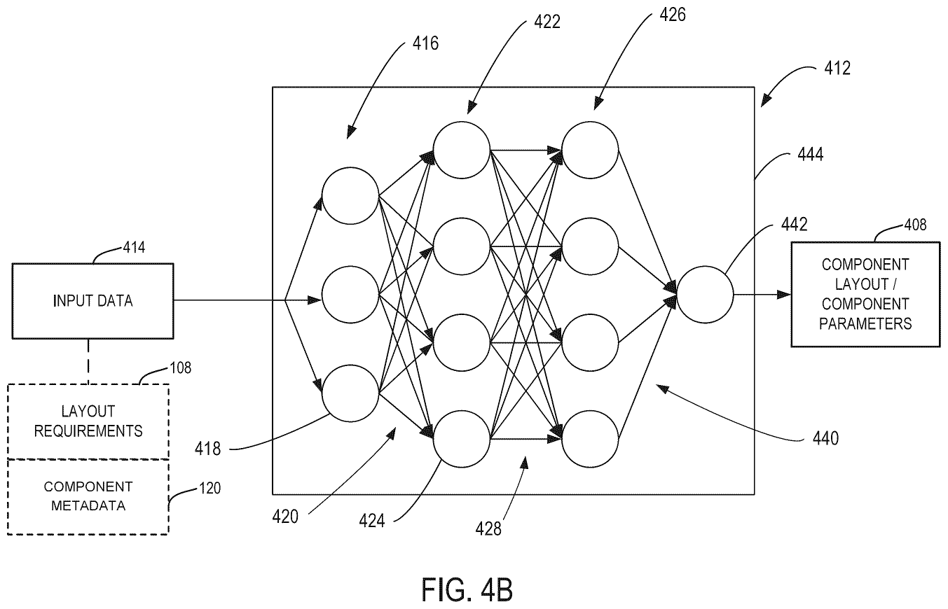

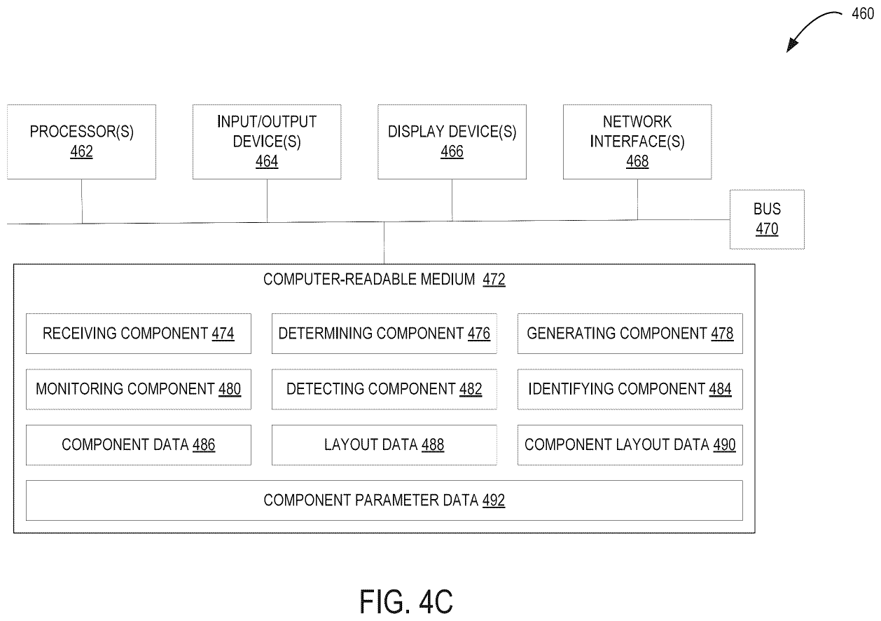

Referring now to FIG. 4A, a block diagram is shown of an exemplary machine-learning-based training system 400 for generating wireless-optimized layouts and configuration parameters for data center computing components. The system 400 may be implemented through software, hardware, firmware, or combinations thereof, and may operate as a cloud-based service, an on-premises application, or an edge-deployed platform according to various implementations. The system 400 illustrated in FIG. 4A is configured to develop and train a predictive model that processes layout requirements and component specifications as inputs and generates optimized spatial arrangements and operational parameters for computing components within a data center environment as outputs.

The system 400 may include a model trainer 402, which executes training procedures on a machine-learning model 404. The model trainer 402 comprises computational logic and processing resources configured to iteratively refine parameters, weights, or structure of the machine-learning model 404 through various learning methodologies. In some implementations, the model trainer 402 may employ supervised learning techniques, wherein the model parameters are adjusted based on labeled examples that associate input conditions with desired output configurations. In other implementations, the model trainer 402 may utilize unsupervised learning approaches that identify patterns or clusters within unlabeled data. In still other implementations, the model trainer 402 may implement reinforcement learning frameworks wherein the model learns optimal configuration strategies through simulated or real-world interactions with data center environments.

The model trainer 402 may execute within a distributed computing infrastructure that enables parallel processing of training data, concurrent evaluation of multiple model variants, or accelerated optimization through specialized hardware such as graphics processing units (GPUs), tensor processing units (TPUs), or application-specific integrated circuits (ASICs). The model trainer 402 may incorporate various optimization algorithms for parameter adjustment, including but not limited to stochastic gradient descent, adaptive moment estimation (Adam), or evolutionary strategies, selecting the appropriate technique based on model architecture, data characteristics, and convergence behavior.

The machine-learning model 404 comprises a structured computational framework designed to learn mappings between input features (such as component specifications, environmental parameters, and performance requirements) and output predictions (such as spatial coordinates, wireless configuration settings, and operational parameters). The machine-learning model 404 may be implemented using various architectural approaches suitable for spatial and configuration optimization tasks. In some aspects, the machine-learning model 404 may comprise a deep neural network with multiple hidden layers, enabling the extraction and transformation of complex feature representations. The neural network architecture may incorporate convolutional layers for processing spatial data represented as grids or matrices, recurrent layers for capturing sequential dependencies in workload patterns, or attention mechanisms for learning correlations between different components or regions within the data center space.

In some aspects, the machine-learning model 404 may utilize decision tree ensembles, graph neural networks, or probabilistic graphical models that capture dependencies between computing components and their associated wireless communication pathways. The model architecture may be designed to account for both discrete decisions (such as component placement in specific locations) and continuous parameters (such as transmit power levels or antenna orientations), potentially through hybrid approaches that combine classification and regression capabilities.

The machine-learning model 404 receives training data from one or more data source(s) 406. The data source(s) 406 comprise repositories, databases, data streams, or simulation engines that provide input-output examples for training the machine-learning model 404. The data source(s) 406 may include historical records from existing data centers, synthetic datasets generated through simulation, or experimental measurements collected from controlled environments. The training examples may associate specific component arrangements with measured wireless performance metrics, thermal conditions, power consumption patterns, or workload execution statistics.

The data source(s) 406 may be implemented using distributed storage systems, cloud-based data lakes, time-series databases, or specialized repositories optimized for machine-learning workflows. In some implementations, the data source(s) 406 may support streaming interfaces that enable continuous model training as new performance data becomes available from operational data center environments. The data preparation pipelines associated with the data source(s) 406 may include preprocessing stages such as normalization, feature extraction, outlier detection, or dimensionality reduction to enhance the quality and efficiency of the training process.

In some aspects, the data source(s) 406 may include layout requirements 108 and component metadata 120, which provide structured inputs that define the constraints, objectives, and parameters for the floor planning optimization task. The layout requirements 108 specify the criteria and constraints that govern the generation of data center floor plans, including thermal boundaries, connectivity objectives, workload affinity requirements, component density targets, and wireless performance thresholds. These requirements may be encoded as quantitative constraints (such as maximum temperature limits, minimum signal strength thresholds, or latency bounds) or qualitative preferences (such as workload co-location guidelines or accessibility considerations).

The layout requirements 108 may be organized in hierarchical structures that reflect different priority levels, enabling the machine-learning model 404 to address some constraints before optimizing other objectives. The layout requirements 108 may also include temporal specifications that account for expected changes in workload patterns, scaling projections, or maintenance schedules, allowing the model to generate floor plans that accommodate future growth or operational variations.

In some aspects, the component metadata 120 refers to the characteristics and capabilities of the computing components that are to be arranged within the data center floor plan. As previously described, the component metadata 120 may include physical attributes (such as dimensions, weight, and form factors), performance specifications (such as processing capacity, memory bandwidth, or storage throughput), wireless communication capabilities (such as supported frequencies, modulation schemes, or antenna configurations), power consumption profiles, and thermal characteristics. The component metadata 120 may be structured as standardized profiles that enable consistent representation and comparison across different component types, manufacturers, or generations.

In some implementations, the component metadata 120 may include parameterized models that predict component behavior under various operating conditions, enabling the machine-learning model 404 to estimate performance metrics for proposed configurations without requiring exhaustive empirical measurements. The predictive models may provide accurate optimization decisions during the floor planning process by capturing relationships between workload intensity, environmental conditions, and performance outcomes.

In some aspects, the machine-learning model 404 processes input data from the data source(s) 406, including the layout requirements 108 and component metadata 120, and generates output predictions in the form of component layout and/or component parameters 408. The component layout portion of the output may indicate the spatial arrangement of computing components within the data center environment, potentially encoded as coordinates within a reference grid, zone assignments, proximity relationships, or orientation specifications. These layout recommendations may refer to the physical positioning of servers, racks, switches, pods, or other computing infrastructure elements in a manner that satisfies wireless connectivity requirements while considering additional factors such as cooling efficiency, power distribution, and operational accessibility.

The component parameters portion of the output may indicate the operational settings, configurations, or states for the computing components within the proposed layout. These parameters may include wireless communication settings (such as frequency band allocations, channel assignments, transmit power levels or beamforming directions), cooling configurations (such as airflow rates, temperature setpoints, or fan speeds), power management settings (such as voltage levels, power capping thresholds, or load balancing directives), or workload scheduling policies. The component parameters complement the spatial layout by indicating how the components should be configured to optimize overall system performance once physically arranged according to the layout recommendations.

The output generated by the machine-learning model 404 during training may be evaluated using a loss function 410. The loss function 410 quantifies the divergence between the model's predictions (component layout and component parameters 408) and designated ground truth or target outcomes. This measurement may provide a numerical assessment of prediction quality that guides the optimization process performed by the model trainer 402. The loss function 410 may incorporate multiple weighted terms that address different aspects of floor plan quality, potentially including wireless performance metrics (such as signal coverage uniformity, interference minimization, or bandwidth utilization), thermal efficiency (such as temperature distribution or cooling effectiveness), power optimization (such as load balancing or energy consumption), and operational considerations (such as maintenance accessibility or expansion capacity).

The computed loss value is provided to the model trainer 402, which uses this feedback to adjust the parameters of the machine-learning model 404 through techniques such as backpropagation, reinforcement learning updates, or evolutionary optimization. This training process continues iteratively, with the model trainer 402 refining the machine-learning model 404 to minimize the loss value across training examples and improve generalization to unseen scenarios.

Upon completion of training, the system 400 produces a trained machine-learning model 412, which represents the trained version of the machine-learning model 404 with parameters configured to generate effective floor plans and component configurations. The trained machine-learning model 412 may be serialized, versioned, and deployed to production environments for real-time inference or decision support. In some implementations, the trained machine-learning model 412 may be compressed, quantized, or optimized for efficiency to enable deployment on resource-constrained platforms or edge devices within the data center infrastructure.

The trained machine-learning model 412 may be integrated with orchestration systems, management interfaces, or automation platforms that implement the generated floor plans and apply the recommended component parameters in operational data center environments. The trained machine-learning model 412 may also support interactive refinement through human-in-the-loop workflows, wherein domain experts can review, adjust, or constrain model recommendations based on practical considerations or specialized knowledge not captured in the training data.

While the exemplary machine-learning-based training system 400 is shown as including a specific arrangement of components, it should be understood that other arrangements are possible. In some aspects, the exemplary machine-learning-based training system 400 may include more or fewer components than that which is depicted. For example, additional data sources may be incorporated to provide supplementary training examples, alternative loss function formulations may be implemented to address specific optimization objectives, or parallel model trainers may be deployed to evaluate multiple architectural variations simultaneously. The system may also be implemented in distributed configurations where components reside on separate physical hardware or virtual environments connected through networking infrastructure. Furthermore, certain components may be combined or subdivided based on specific implementation requirements, computational resource availability, or organizational preferences. The architecture depicted in FIG. 4A represents one example that illustrates the functional relationships between key system elements, but should not be construed as limiting the scope of possible implementations.

Referring now to FIG. 4B, a block diagram illustrating a system with an example of a trained machine-learning model 412, is depicted in accordance with aspects of the present disclosure. The system operates by processing input data 414 related to computing components and layout requirements to produce component layout and component parameters 408 that maximize wireless communication efficiency while accommodating physical constraints.

In some aspects, the trained machine-learning model 412 may include a neural network architecture 444. Input data 414 is provided to the machine-learning model 412 and may include layout requirements 108 and component metadata 120 as previously described. The combination of layout requirements 108 and component metadata 120 provides the context for the machine-learning model to generate optimized layouts. In some implementations, this data may be pre-processed through feature extraction, normalization, or encoding before being provided to the model.

The neural network architecture 444 may include an input layer 416 composed of multiple input neurons, such as representative input neuron 418. The input layer 416 serves as the entry point for the structured data into the neural network and maps feature dimensions to corresponding neurons. Each input neuron may act as a receptor for a specific parameter or attribute from the input data 414, converting this information into activations that propagate through the network 444. In some aspects, the input layer 416 may incorporate embedding mechanisms that convert categorical or discrete features into dense vector representations suitable for processing by subsequent network layers.

In some aspects, each input neuron may apply normalization, scaling, or transformation functions to standardize the incoming data. The number of neurons in the input layer 416 may correspond to the dimensionality of the feature space, which may range from dozens to hundreds to thousands to millions of parameters depending on the complexity of the layout optimization task. In some implementations, the input neurons may be grouped into logical clusters that handle related features, such as wireless performance metrics, physical constraints, or component dependencies.

Neural pathways 420 connect the input layer 416 to the first hidden layer 422. The neural pathways 420 represent weighted connections that transform the activations from the input layer into signals for the first hidden layer. Each connection may carry a weight value that was determined during the training phase of the model. The weights encode the learned relationships between input features and intermediate representations that contribute to layout optimization. In some aspects, the neural pathways 420 may incorporate attention mechanisms that dynamically adjust the importance of different input features based on their relevance to the current optimization context.

A first hidden layer 422 comprises multiple neurons that perform non-linear transformations on the weighted signals received from the input layer. A representative neuron 424 within this layer illustrates the computational units that process these signals. Each neuron applies an activation function to the sum of its weighted inputs, introducing non-linearity that enables the network to learn complex patterns and relationships. The first hidden layer 422 may extract intermediate features related to component clustering patterns, wireless signal propagation characteristics, thermal distribution effects, or spatial efficiency metrics. In some implementations, the first hidden layer 422 may use specialized activation functions tailored to the layout optimization domain, such as functions that model wireless signal attenuation or thermal gradient behaviors.

Neural pathways 428 connect the first hidden layer 422 to a second hidden layer 426. These connections facilitate the flow of information through the network, allowing the model to build increasingly abstract representations of optimal layout characteristics. The weights associated with these pathways encode higher-order relationships between the intermediate features extracted by the first hidden layer. In some aspects, these connections may include residual or skip connections that allow certain signals to bypass layers, improving gradient flow during training and enabling the learning of more complex layout optimization functions.

The second hidden layer 426 performs additional transformations on the signals received from the first hidden layer. This layer may identify more complex patterns related to wireless connectivity optimization, such as ideal clustering arrangements, interference minimization strategies, or cooling efficiency maximization techniques. In some implementations, the second hidden layer 426 may include specialized neurons that model specific aspects of wireless communication in data center environments, such as multipath propagation effects, frequency band allocation, or dynamic power adjustment strategies.

Neural pathways 440 connect the second hidden layer 426 to the output layer 442. These final connections transform the high-level abstract representations from the hidden layers into concrete output values that specify component placement coordinates, orientation parameters, or configuration settings. The weights of these connections encode the relationships between the abstract features and the specific output parameters required for data center layout optimization. In some aspects, these neural pathways 440 may incorporate constraint enforcement mechanisms that ensure the generated outputs satisfy physical feasibility requirements or wireless performance thresholds.

The output layer 442 generates the component layout and component parameters 408 based on the processed signals received through the neural network. The output layer 442 may generate various types of outputs, including spatial coordinates for component placement, orientation angles for directional antennas, transmission power settings for wireless interfaces, or channel assignments for frequency allocation. The output values collectively provide a comprehensive layout plan that optimizes wireless connectivity while satisfying physical constraints. In some implementations, the output layer may include post-processing functions that refine the generated parameters to ensure they fall within valid ranges or comply with specific floor planning rules.

In certain implementations, the trained machine-learning model 412 may operate as part of a feedback loop system, where the outcomes of implemented layouts are monitored and used to refine the model's predictions over time. This adaptive approach enables continuous improvement of layout optimization strategies as more operational data becomes available or as wireless technology evolves.

While the exemplary system with a trained machine-learning model 412 is shown in FIG. 4B as including a specific arrangement of components, it should be understood that other arrangements are possible. In some aspects, the system may include more or fewer components than that which is depicted. For example, the neural network architecture 444 could be configured with different numbers of hidden layers beyond the first hidden layer 422 and second hidden layer 426 shown, or with varying neuron counts within each layer to accommodate different complexity requirements. The input layer 416 might be expanded to process additional categories of layout constraints or component metadata, while the output layer 442 could be modified to produce more granular configuration parameters. Alternative implementations might incorporate different types of neural pathways beyond those shown at 420, 428, and 440, such as bidirectional connections or attention-based mechanisms that highlight relevant feature interactions. The system might also implement different activation functions within the neurons like representative neuron 424, or introduce regularization techniques to improve generalization across diverse data center environments. The architecture depicted in FIG. 4B represents one example that illustrates the functional relationships between key system elements, but should not be construed as limiting the scope of possible implementations for generating optimized component layouts and parameters 408.

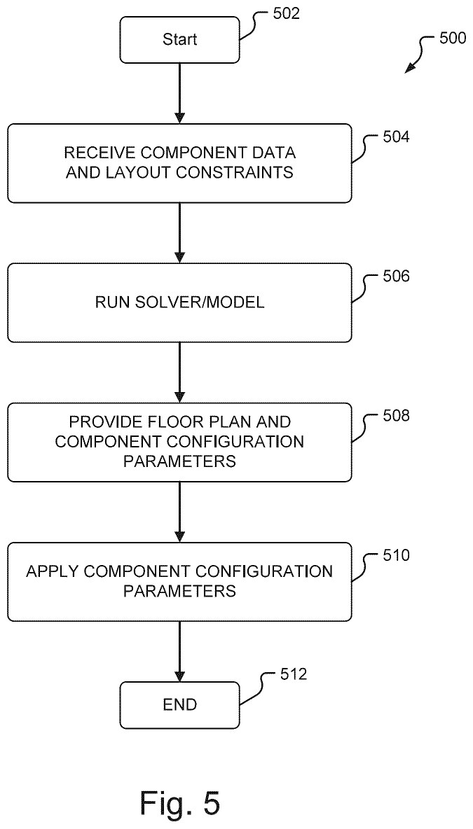

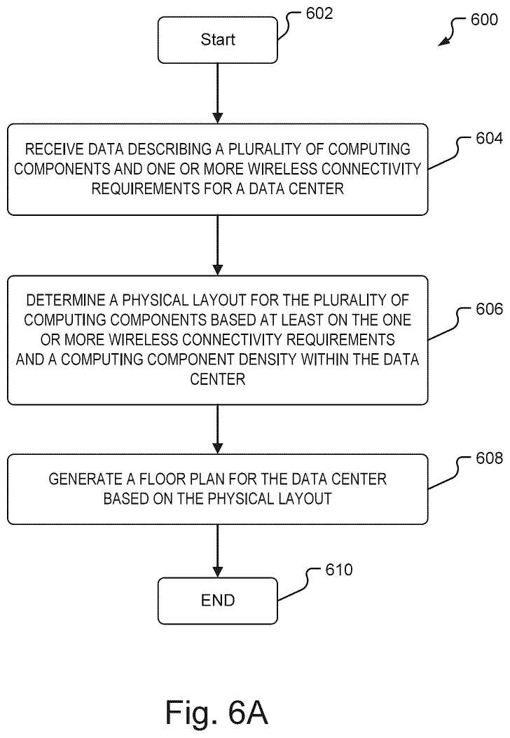

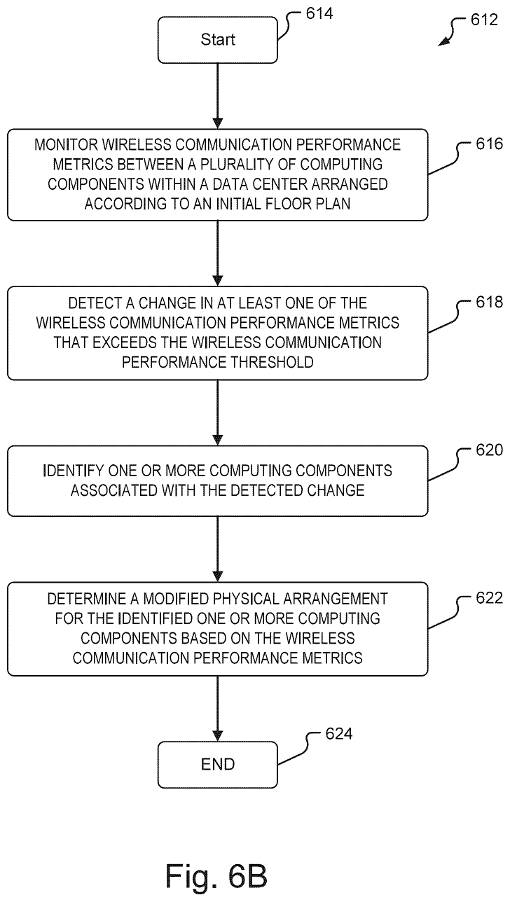

FIG. 4C depicts an example processing system 460 configured to perform various aspects described herein, including, for example, method 500, method 600, and method 612 as described herein with respect to FIGS. 5-6B.

Processing system 460 is generally an example of an electronic device configured to execute computer-executable instructions, such as those derived from compiled computer code, including without limitation personal computers, tablet computers, servers, smartphones, smart devices, wearable devices, augmented and/or virtual reality devices, and others.

In the depicted example, processing system 460 includes one or more processors 462, one or more input/output devices 464, one or more display devices 466, one or more network interfaces 468 through which processing system 460 is connected to one or more networks (e.g., a local network, an intranet, the Internet, or any other group of processing systems communicatively connected to each other), and computer-readable medium 472. In the depicted example, the aforementioned components are coupled by a bus 470, which may generally be configured for data exchange amongst the components. Bus 470 may be representative of multiple buses, while only one is depicted for simplicity.

Processor(s) 462 are generally configured to retrieve and execute instructions stored in one or more memories, including local memories like computer-readable medium 472, as well as remote memories and data stores. Similarly, processor(s) 462 are configured to store application data residing in local memories like the computer-readable medium 472, as well as remote memories and data stores. More generally, bus 470 is configured to transmit programming instructions and application data among the processor(s) 462, display device(s) 466, network interface(s) 468, and/or computer-readable medium 472. In certain aspects, processor(s) 462 are representative of a one or more central processing units (CPUs), graphics processing unit (GPUs), tensor processing unit (TPUs), accelerators, and other processing devices.

Input/output device(s) 464 may include any device, mechanism, system, interactive display, and/or various other hardware and software components for communicating information between processing system 460 and a user of processing system 460. For example, input/output device(s) 464 may include input hardware, such as a keyboard, touch screen, button, microphone, speaker, and/or other device for receiving inputs from the user and sending outputs to the user.

Display device(s) 466 may generally include any sort of device configured to display data, information, graphics, user interface elements, and the like to a user. For example, display device(s) 466 may include internal and external displays, such as an internal display of a tablet computer or an external display for a server computer or a projector. Display device(s) 466 may further include displays for devices such as augmented, virtual, and/or extended reality devices. In various aspects, display device(s) 476 may be configured to display a graphical user interface.

Network interface(s) 468 provides processing system 460 with access to external networks and, thereby, to external processing systems. Network interface(s) 468 can generally be any hardware and/or software capable of transmitting and/or receiving data via a wired or wireless network connection. Accordingly, a network interface(s) 468 can include a communication transceiver for sending and/or receiving any wired and/or wireless communication.

Computer-readable medium 472 may be a volatile memory, such as a random access memory (RAM), or a nonvolatile memory, such as nonvolatile random access memory (NVRAM), or the like. Computer-readable medium 472 includes several functional components implemented as software modules, firmware, or programmable logic, including receiving component 474, determining component 476, generating component 478, monitoring component 480, detecting component 482, identifying component 484, component data 486, layout data 488, component layout data 490, and component parameter data 492. In some aspects, the computer-readable medium 472 may include the layout engine 104 described in relation to FIG. 1. In some aspects, the functionality of the layout engine 104 may be performed by one or more of the components depicted in FIG. 4C.

Receiving component 474 is configured to receive data describing a plurality of computing components and wireless connectivity requirements for a data center. This component may implement communication protocols, data parsing algorithms, or validation procedures to process inputs from various sources such as component repositories, specification databases, or user interfaces.

Determining component 476 is configured to determine a physical layout for the plurality of computing components based at least on wireless connectivity requirements and computing component density. This component may implement layout algorithms, optimization solvers, or machine-learning models that evaluate potential arrangements against wireless performance metrics, spatial constraints, and density objectives.

Generating component 478 is configured to generate a floor plan for the data center based on the physical layout. This component may produce structured output formats, visualization data, or implementation instructions derived from the optimized layout determination, suitable for deployment through data center management systems.

Monitoring component 480 is configured to monitor wireless communication performance metrics between computing components arranged according to an initial floor plan. This component may implement telemetry collection, performance analysis, or trend detection algorithms that assess the operational effectiveness of deployed wireless connectivity paths.

Detecting component 482 is configured to detect changes in wireless communication performance metrics that exceed predetermined thresholds. This component may implement comparison logic, statistical analysis techniques, or anomaly detection algorithms that identify significant deviations from expected performance patterns.

Identifying component 484 is configured to identify computing components associated with detected changes in wireless performance. This component may implement correlation analysis, fault isolation techniques, or network topology traversal algorithms that locate specific components requiring attention or modification.

Component data 486 stores information about the plurality of computing components within the data center, potentially including physical specifications, wireless capabilities, power requirements, thermal characteristics, or workload profiles. This data structure corresponds to the component metadata described in relation to FIGS. 1 and 4A-4B.

Layout data 488 stores information about spatial arrangements, physical constraints, or environmental factors within the data center that influence component placement decisions. This data structure may include coordinate systems, zone definitions, or obstacle maps that guide layout optimization.

Component layout data 490 stores the output of the layout determination process, representing the physical positions, orientations, or groupings of computing components within the optimized floor plan. This data structure corresponds to the component layout outputs described in relation to FIGS. 1 and 4A-4B.

Component parameter data 492 stores configuration values for the computing components, including wireless communication settings, thermal management parameters, or power distribution configurations. This data structure corresponds to the component parameters outputs described in relation to FIGS. 1 and 4A-4B.

The functional components within computer-readable medium 472 interact with one another to implement the methods described in FIGS. 5-6B. For example, receiving component 474 may provide input data to determining component 476, which generates layout configurations stored in component layout data 490. Similarly, monitoring component 480 may detect performance changes by detecting component 482, which triggers identifying component 484 to locate affected components for reconfiguration.

Note that FIG. 4C is just one example of a processing system consistent with aspects described herein, and other processing systems having additional, alternative, or fewer components are possible consistent with this disclosure. In some aspects, the architectural components depicted in FIG. 4C enables the implementation of wireless-optimized data center floor planning as described throughout this disclosure, providing the computational foundation for methods 500, 600, and 612 illustrated in FIGS. 5-6B.

Referring now to FIG. 5, a flow diagram illustrates an exemplary method 500 for generating and implementing a wireless-optimized data center floor plan in accordance with aspects of the present disclosure. The method 500 may be implemented by a layout engine (e.g., layout engine 104 of FIG. 1), orchestration platform, or machine-learning inference module as described in connection with the preceding figures. While the operations are shown in a particular sequence, it should be understood that these operations may be performed in different orders, in parallel, or iteratively as required by system configurations.

The method 500 begins at block 502, which represents an initialization state. This initialization may include activating system components, loading configuration data, establishing communication channels with computing components, or preparing processing environments for subsequent operations. In some aspects, the initialization at block 502 may be triggered automatically based on predetermined schedules, detected changes in wireless performance metrics, or modifications to data center infrastructure. In other aspects, the initialization may be manually initiated through a user interface in response to administrative commands or planning requirements. The initialization process may also include verification of system readiness, validation of input data sources, and establishment of communication channels with monitoring systems that provide real-time telemetry about wireless performance within the data center environment.

At block 504, the method 500 proceeds to receive component data and layout constraints. This operation involves the ingestion and processing of structured information describing the computing components to be positioned within the data center as well as the constraints that govern their arrangement. As previously described, the component data may include physical specifications (such as dimensions, weight, and form factor), performance characteristics (such as processing capacity, memory resources, or storage capabilities), wireless communication parameters (such as supported frequency bands, transmitter power levels, or antenna configurations), power consumption profiles, thermal output measurements, and workload affinities. The component data may provide the system with information to utilize the physical and operational requirements of each element that will be positioned within the floor plan.

The layout constraints received at block 504 may encompass various requirements and limitations that influence component placement decisions. As previously described, these constraints may include spatial boundaries defining the available floor area, structural limitations such as load-bearing capacity or ceiling height, environmental factors such as ambient temperature variations or air circulation patterns, regulatory requirements related to power density or electromagnetic emissions, and operational objectives such as workload clustering or component redundancy. Wireless connectivity constraints may be particularly emphasized, including minimum signal strength thresholds, maximum interference tolerances, bandwidth availability requirements, or latency bounds for communicating components. The system may also ingest historical performance data, predicted workload patterns, or growth projections that influence long-term floor planning decisions.

At block 506, the method 500 executes a solver or model to process the received data and generate optimized layouts. In implementations utilizing an optimization solver, the system may employ algorithms such as linear programming, constraint satisfaction, genetic algorithms, or simulated annealing to identify arrangements that maximize wireless performance while satisfying other constraints. The solver may execute multiple iterations, progressively refining candidate solutions based on objective function evaluations or constraint violation assessments.

In implementations utilizing a machine-learning model, as described in relation to FIGS. 4A and 4B, the system may employ a trained neural network or other predictive architecture to translate input features into optimized layout coordinates and configuration parameters. The model may have been previously trained on historical data correlating component arrangements with wireless performance outcomes, enabling inference-time predictions that incorporate learned patterns and relationships. The model execution may include feature preprocessing, multi-layer transformations, attention mechanisms that focus on parameters, and post-processing steps that ensure output feasibility. In some aspects, the solver or model execution at block 506 may incorporate simulation capabilities that predict wireless signal propagation throughout candidate layouts, enabling proactive assessment of communication performance before physical deployment.

Following the computational analysis at block 506, the method 500 proceeds to block 508, where the system provides a floor plan and component configuration parameters. This operation transforms the internal representations generated by the solver or model into concrete, implementable specifications for the data center layout. The floor plan output may specify spatial coordinates for each computing component within a reference grid or physical coordinate system, potentially including three-dimensional positioning to account for vertical stacking or tiered arrangements. The floor plan may be encoded in standardized formats compatible with computer-aided design systems, building information modeling platforms, or data center infrastructure management tools. Visualization elements may accompany the floor plan, highlighting wireless connectivity paths, signal strength contours, thermal gradients, or workload affinities between positioned components.

The component configuration parameters provided at block 508 complement the spatial layout by specifying operational settings for each computing component within the arranged floor plan. These parameters may include wireless communication configurations such as frequency channel assignments, transmission power levels, modulation schemes, antenna orientation angles, or beamforming directions. Additional parameters may address thermal management settings such as fan speeds or airflow directions, power distribution configurations such as load balancing or redundancy paths, and workload scheduling policies that optimize resource utilization across the arranged components. The configuration parameters may be encoded in machine-readable formats suitable for automated deployment through orchestration platforms or management interfaces.

At block 510, the method 500 applies the generated component configuration parameters to the physical or virtual infrastructure. This implementation phase translates the optimized design into operational reality through programmatic or manual interventions. The application of configuration parameters may involve communication with wireless controller interfaces, network management systems, server configuration agents, or power distribution units. In some aspects, instructions may be issued to adjust transmitter power levels, reconfigure antenna orientations, reassign frequency channels, or modify modulation schemes according to the optimized parameters. In aspects where physical component relocation is required, the system may generate instructions for data center personnel or robotic positioning systems to move components according to the floor plan coordinates.

The application phase at block 510 may implement progressive or phased deployment strategies to minimize service disruption during reconfiguration. For instance, temporary wireless communication paths may be established before component relocation to maintain network connectivity during transition periods. The system may also incorporate verification mechanisms that confirm successful parameter application through feedback loops, telemetry validation, or functional testing of established wireless links. In advanced implementations, the application phase may leverage software-defined networking capabilities to dynamically reconfigure communication pathways as components are repositioned or reoriented according to the floor plan.

The method 500 concludes at block 512, representing a completion state for the current optimization cycle. This termination point may correspond to successful implementation of the floor plan and configuration parameters, achievement of target performance metrics, or transition to a monitoring phase that evaluates the effectiveness of the applied changes. In some aspects, the completion at block 512 may trigger notification systems that inform administrators about the implemented changes, generate documentation of the current configuration state, or update historical records for future reference. The system may transition to an idle state awaiting the next optimization cycle, or may initiate continuous monitoring processes that track wireless performance metrics for potential future adjustments.

In various aspects, the method 500 may incorporate additional operations not explicitly shown in FIG. 5, such as validation steps that verify the feasibility of generated layouts, simulation phases that predict performance outcomes before implementation, or feedback mechanisms that adjust optimization parameters based on measured results. The method 500 may execute as a discrete process with clear start and end points, or may operate as a continuous optimization loop that responds dynamically to changing conditions within the data center environment. The method 500 may be implemented through distributed processing architectures, with different components handling specialized aspects such as data collection, computational analysis, visualization, or implementation control.

Referring now to FIG. 6A, a flowchart illustrating a method 600 for generating a wireless-optimized data center floor plan is depicted, in accordance with aspects of the present disclosure, at least some concepts of which have been discussed with reference to FIGS. 1-5. The method 600 may be performed by one or more processing elements associated with the layout engine described with reference to FIG. 1, such as the one or more processors and memory devices. In one aspect, method 600 can be implemented in one or more circuits. As may be appreciated, the one or more circuits may be included in the layout engine 104, the link monitor or site survey module 124 of FIG. 1, and/or correspond to or involve elements described in the machine-learning-based training system 400 of FIG. 4A.

The method 600 begins at block 602, which represents a start condition for the wireless-optimized floor planning process. This initialization may establish computational resources, access to component databases, and communication channels with layout visualization systems or orchestration interfaces.

The method 600 proceeds to block 604, where the system receives data describing a plurality of computing components and one or more wireless connectivity requirements for a data center. In some aspect, the data describing a plurality of computing components may include specifications for various infrastructure elements such as servers, trays, racks, pods, or clusters. For each component, the data may comprise physical attributes (dimensions, weight, form factor), wireless communication capabilities (supported frequencies, antenna configurations, signal characteristics), power consumption profiles, thermal properties, and workload affinities. In some aspects, wireless connectivity requirements received at block 604 may define performance parameters that are to be satisfied by the resulting floor plan. These requirements may include signal strength thresholds, interference tolerances, bandwidth guarantees, latency bounds, or reliability metrics for wireless communication paths between components. In some aspects, such requirements may be expressed as quantitative constraints with minimum acceptable values, target operational ranges, or optimization objectives. The requirements may also include regulatory considerations related to radio frequency emissions, power density limitations, or compliance with industry standards for wireless communication in data center environments.

Method 600 proceeds to block 606 with, determining a physical layout for the plurality of computing components based at least on the one or more wireless connectivity requirements and a computing component density within the data center. In some aspects, the layout engine may determine a physical layout. In some aspects, the process of determining the layout may evaluate potential spatial arrangements of components to identify configurations that satisfy wireless performance criteria while maximizing utilization of available floor space. In some aspects, the block 606 may employ various computational approaches, including optimization algorithms, constraint satisfaction techniques, or machine-learning models as described in relation to FIGS. 4A and 4B. When utilizing optimization algorithms, the system may iteratively refine candidate layouts through objective function evaluations that assess wireless signal propagation, interference patterns, or connectivity resilience. When employing machine-learning models, the system may leverage trained neural networks that translate input features into optimized component coordinates based on patterns learned from historical performance data.

In some aspects, the physical layout determined at block 606 may be based on a wireless connectivity architecture independent of cable routing paths. This independence from physical cabling constraints enables more flexible arrangements that prioritize wireless performance metrics over traditional infrastructure limitations. The determination process may consider wireless propagation characteristics, including but not limited to, signal frequency, bandwidth, modulation scheme, signal strength, data rate, latency, bit error rate, or signal interference. In some aspects, considerations beyond wireless connectivity, such as cooling requirements or power delivery requirements for the computing components may be incorporated when determining the physical layout. The system may adjust component placements to balance thermal management objectives, optimize power distribution efficiency, or accommodate infrastructure limitations while maintaining wireless connectivity performance. In some aspects, block 606 may leverage machine-learning models trained to generate data center floor plans, enabling the system to incorporate complex, non-linear relationships between component attributes and performance outcomes.

Method 600 then proceeds to block 608, with generating a floor plan for the data center based on the physical layout determined at block 606. This operation transforms the computational representation of component arrangements into a layout specification for a data center. The generated floor plan may include spatial coordinates for each component, orientation parameters, elevation specifications, and logical groupings of related elements. In some aspects, the floor plan may indicate positions of the plurality of computing components and corresponding wireless connectivity paths between them, providing a visualization of the wireless-enabled infrastructure.

The floor plan generated at block 608 may be in formats compatible with data center infrastructure management systems, computer-aided design platforms, or visualization tools. The floor plan may incorporate visual indicators of wireless signal strength contours, interference zones, or throughput capacity to aid in deployment and verification. In some aspects, the generation process may include validation steps that confirm the feasibility of the proposed arrangement against physical constraints, wireless performance models, or operational requirements before finalizing the output.

Method 600 then concludes at block 610, representing completion of the floor planning process. This termination point corresponds to the successful generation of the wireless-optimized floor plan, which may then be implemented through physical deployment, configuration management systems, or further refinement processes. In some implementations, the system may transition to monitoring or adjustment phases, wherein wireless communication performance metrics are monitored and physical arrangements may be modified in response to detected changes in performance.

The method 600 enables data center operators to systematically generate floor plans that leverage wireless connectivity to enhance flexibility, scalability, and performance. By determining physical layouts based primarily on wireless communication parameters rather than cable routing constraints, the method facilitates more efficient space utilization, simplified expansion, and adaptive reconfiguration in response to changing operational requirements. In some aspects, such an approach enables dynamic adjustment of physical layouts to scale computing components without adding wired infrastructure, providing significant operational advantages in rapidly evolving computing environments.

Referring now to FIG. 6B, a flowchart illustrating a method 612 for dynamically reconfiguring wireless-optimized data center component arrangements is depicted, in accordance with aspects of the present disclosure, at least some concepts of which have been discussed with reference to FIGS. 1-6A. The method 612 may be performed by one or more processing elements, such as the one or more processors coupled to memory devices that store wireless communication performance thresholds. In one aspect, method 612 can be implemented in one or more circuits. As may be appreciated, the one or more circuits may be included in the layout engine 104, the link monitor or site survey module 124 of FIG. 1, and/or correspond to or involve elements described in the feedback loop 148 of FIG. 1.

The method 612 begins at block 614, which represents a start condition for the dynamic reconfiguration process. This initialization may occur after an initial floor plan has been implemented using the method depicted in FIG. 6A, establishing baseline wireless connectivity between computing components within the data center. The start condition may be triggered automatically based on scheduled monitoring cycles, detection of performance anomalies, or reconfiguration requests from data center management systems.

The method 612 proceeds to block 616, where the system monitors wireless communication performance metrics between a plurality of computing components within a data center arranged according to an initial floor plan. In some aspects, the monitoring operation includes where processors monitor such performance metrics for components arranged according to an initial plan. The monitoring process may involve collecting telemetry data from deployed components, analyzing signal quality measurements, or aggregating performance statistics from wireless communication interfaces.

The wireless communication performance metrics monitored at block 616 may include signal strength, data throughput, latency, bit error rate, packet loss, signal-to-noise ratio, and/or channel quality indicators. These metrics provide quantitative assessments of wireless connectivity quality and reliability between computing components. The monitoring system may employ distributed sensor networks, embedded telemetry agents within computing components, or centralized network analysis tools to gather these metrics continuously or at specified intervals.

The monitoring operation at block 616 establishes a baseline of expected performance for the wireless connectivity paths established in the initial floor plan. This baseline may account for normal operational variations, environmental factors, or workload-dependent fluctuations in wireless communication characteristics. The monitoring system may apply statistical analysis techniques to distinguish between normal performance variations and significant deviations that warrant intervention, potentially utilizing machine-learning algorithms to identify patterns indicative of developing connectivity issues.

At block 618, the method 612 detects a change in at least one of the wireless communication performance metrics that exceeds the wireless communication performance threshold. This detection operation may include where processors identify performance changes that cross predetermined thresholds stored in memory. The detection may involve comparing current metric values against static thresholds, analyzing trend data to identify progressive degradation, or applying anomaly detection algorithms to identify unusual performance patterns.

The performance thresholds used for detection at block 618 may be configured based on workload requirements, service level agreements, or operational priorities within the data center. Different thresholds may apply to different types of computing components, communication pathways, or application workloads based on their specific performance requirements. For example, components supporting latency-sensitive applications may have more stringent thresholds for acceptable delay variations compared to components handling batch processing workloads.

The detection process at block 618 may incorporate various filtering or validation techniques to minimize false positives due to transient conditions or measurement artifacts. These techniques may include temporal averaging, statistical outlier rejection, or correlation analysis across multiple performance metrics. The system may also consider contextual factors such as concurrent workload changes, scheduled maintenance activities, or environmental variations when evaluating the significance of detected performance changes.

At block 620, the method 612 identifies one or more computing components associated with the detected change in wireless communication performance. This identification operation may include where processors identify components associated with detected performance changes. The identification process may involve tracing communication pathways affected by performance degradation, analyzing connectivity graphs to isolate affected nodes, or correlating performance anomalies with specific component locations or configurations.

The identification at block 620 may distinguish between components that are sources of performance issues and those that are merely affected by issues originating elsewhere in the wireless network. This distinction enables targeted intervention focused on root causes rather than symptoms of wireless performance degradation. The identification process may leverage topology information, communication flow analysis, or fault isolation techniques to precisely locate the components requiring attention.

In complex environments with multiple interdependent wireless communication pathways, the identification process may employ graph analysis algorithms to understand propagation patterns of performance degradation across the component network. This analysis may reveal clusters of affected components, communication pathways, or vulnerability points that warrant prioritized attention during subsequent reconfiguration efforts.

At block 622, the method 612 determines a modified physical arrangement for the identified one or more computing components based on the wireless communication performance metrics. This determination operation may include where processors determine modified arrangements based on performance metrics. The determination process evaluates alternative physical positions, orientations, or configurations for the affected components to restore or enhance wireless connectivity performance.

The determination at block 622 may employ optimization algorithms, simulation models, or machine-learning techniques to identify arrangements that address the detected performance issues while minimizing disruption to the overall data center operation. These computational approaches may consider factors such as signal propagation patterns, interference sources, physical obstructions, or workload communication patterns when evaluating potential modifications.

In some aspects, the determination process may generate specific instructions for physically relocating the identified components according to the modified arrangement. These instructions may include detailed movement plans, sequencing information, or handling requirements to ensure proper implementation of the recommended changes. In some aspects, the determination may also include planning for temporary wireless communication paths to maintain network connectivity during the physical relocation process, ensuring continuity of service during reconfiguration activities.

The modified arrangement determined at block 622 may involve various types of changes, including repositioning components within the data center space, reorienting directional antennas, adjusting power levels of wireless transmitters, or reconfiguring frequency allocations to optimize signal quality and minimize interference. The determination process balances the potential performance improvements against practical considerations such as implementation difficulty, service disruption risk, or resource requirements.

The method 612 concludes at block 624, representing completion of the dynamic reconfiguration planning process. This termination point corresponds to successful determination of the modified physical arrangement, which may then be implemented through the orchestration interface 144 described in FIG. 1. In some aspects, following implementation of the modified arrangement, the system may configure wireless communication devices to implement permanent wireless communication paths according to the new configuration, establishing stable connectivity for ongoing operations.

The method 612 enables continuous optimization of data center layouts based on actual wireless performance measurements rather than theoretical models or static assumptions. By monitoring real-time performance metrics, detecting significant changes, identifying affected components, and determining appropriate physical modifications, the method provides a comprehensive approach to maintaining optimal wireless connectivity as conditions evolve within the data center environment. This adaptive capability enhances the resilience, efficiency, and performance of wireless-optimized data center infrastructures, enabling them to respond dynamically to changing operational requirements or environmental conditions.

In view of the above, it should be appreciated that aspects of the present disclosure provide an apparatus comprising: one or more memory devices to store data describing a plurality of computing components and one or more wireless connectivity requirements for a data center; and one or more processors, coupled to the one or more memory devices, to: determine a physical layout for the plurality of computing components based at least on the one or more wireless connectivity requirements and a computing component density within the data center; and generate a floor plan for the data center based on the physical layout. In some aspects, the plurality of computing components comprises at least one of a server, a tray, a rack, a pod, switch, and/or a cluster. In some aspects, the physical layout is determined based on a wireless connectivity architecture independent of cable routing paths. In some aspects, the one or more processors are further to: obtain a measure of wireless communication parameter between the plurality of computing components; and determine a placement of one or more computing components of the plurality of computing components based on the measure of the wireless communication parameter. In some aspects, the one or more processors are further to: position the plurality of computing components within the floor plan based on a threshold associated with a wireless communication parameter for one or more communicating components of the plurality of computing components. In some aspects, the threshold associated with the wireless communication parameter includes at least one wireless propagation characteristic comprising at least one of: signal frequency, bandwidth, modulation scheme, signal strength, data rate, latency, bit error rate, or signal interference. In some aspects, the one or more processors are further to: adjust the physical layout based on a cooling requirement of one or more computing components of the plurality of computing components within the data center. In some aspects, the one or more processors are further to: modify the physical layout based on a power delivery requirement of one or more computing components of the plurality of computing components within the data center. In some aspects, the floor plan indicates positions of the plurality of computing components and corresponding wireless connectivity paths between the plurality of computing components. In some aspects, the one or more processors are further to: transmit a configuration to at least one wireless communication device to configure a wireless connectivity path between a pair of computing components of the plurality of computing components. In some aspects, the one or more processors are further to: reconfigure physical positions of one or more computing components of the plurality of computing components in response to changes in wireless communication performance. In some aspects, the one or more processors are further to: input data describing the plurality of computing components within the data center and the one or more wireless connectivity requirements into a machine-learning model trained to generate data center floor plans, and obtain, from the machine-learning model, the floor plan for the data center. In some aspects, the one or more processors are further configured to dynamically adjust the physical layout to scale a number of computing components within the data center based on at least one of a modified computing requirements or modified wireless connectivity requirements, without adding wired infrastructure. In some aspects, the one or more processors are further configured to determine and configure wireless connectivity paths in response to at least one of an incremental increase or incremental decrease in a number of computing components.

In view of the above, it should be appreciated that aspects of the present disclosure provide a machine-readable medium having data stored thereon, which when executed by one or more processors, cause the one or more processors to: receive data describing a plurality of computing components and one or more wireless connectivity requirements for a data center; determine a physical layout for the plurality of computing components based at least on the one or more wireless connectivity requirements and a computing component density within the data center; and generate a floor plan for the data center based on the physical layout. In some aspects, the plurality of computing components comprises at least one of a server, a tray, a rack, a pod, or a cluster. In some aspects, the physical layout is determined based on a wireless connectivity architecture independent of cable routing paths. In some aspects, the one or more processors are to: adjust the physical layout based on a cooling requirement of one or more computing components of the plurality of computing components within the data center and a power delivery requirement of one or more computing components of the plurality of computing components within the data center.

In view of the above, it should be appreciated that aspects of the present disclosure provide an apparatus comprising: one or more memory devices to store a wireless communication performance threshold; and one or more processors, coupled to the one or more memory devices, to: monitor wireless communication performance metrics between a plurality of computing components within a data center arranged according to an initial floor plan; detect a change in at least one of the wireless communication performance metrics that exceeds the wireless communication performance threshold; identify one or more computing components associated with the detected change; and determine a modified physical arrangement for the identified one or more computing components based on the wireless communication performance metrics. In some aspects, the wireless communication performance metrics comprise at least one of signal strength, data throughput, latency, bit error rate, packet loss, signal-to-noise ratio, or channel quality indicator. In some aspects, the one or more processors are to: generate instructions for physically relocating the identified one or more computing components according to the modified physical arrangement; and transmit the instructions to a data center management system for implementation. In some aspects, the one or more processors are to: determine a temporary wireless communication path to maintain network connectivity during physical relocation of the identified one or more computing components; configure one or more wireless communication devices to implement the temporary wireless communication path; and after physical relocation of the identified one or more computing components, configure the one or more wireless communication devices to implement a permanent wireless communication path according to the modified physical arrangement.

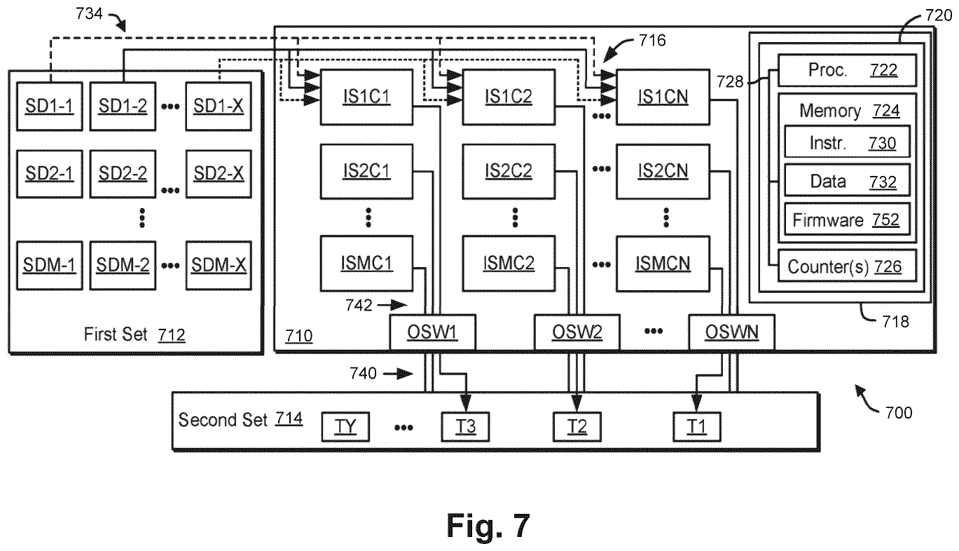

FIG. 7 illustrates a block diagram of a system 700 that includes switching circuitry 710 (sometimes referred to as a “fabric”) positioned between first and second sets 712 and 714 of devices, in accordance with at least one embodiment. By way of a non-limiting example, the system 700 may be implemented as a GPU-to-GPU link system (e.g., a NVLINK® GPU-to-GPU interconnect system) in which the switching circuitry 710 may include one or more GPU-to-GPU switches (e.g., one or more NVSWITCH™ switches). The system 700 may implement (e.g., be a component of) other systems, such as a data center, a cloud computing system, a machine learning system (e.g., utilizing one or more neural networks), an autonomous vehicle, medical imaging equipment, and/or the like.

Each of the first and second sets 712 and 714 may be implemented as a GPU, a parallel processing unit, a central processing unit (“CPU”), data processing unit (“DPU”), a controller, a switch, switching circuitry, a memory device, and/or the like. By way of a non-limiting example, the first set 712 has been illustrated as including a number “M*X” of devices, which are illustrated as devices SD1-1 to SDM-X. However, the set 712 may include any number of devices including a single device. For ease of illustration, in FIG. 7, the devices SD1-1 to SDM-X have been illustrated as being arranged in a two-dimensional array that includes a number “M” of rows and a number “X” of columns. The second set 714 has been illustrated as including a number “Y” of devices, which are illustrated as devices T1-TY, but the second set 714 may include any number of devices including a single device. Further, one or more devices may be members of both of the sets 712 and 714. Thus, the sets 712 and 714 are not mutually exclusive and may include one or more of the same devices. Therefore, in at least one embodiment, the switching circuitry 710 may allow any of the devices SD1-1 to SDM-X in the first set 712 to communicate with any of the devices SD1-1 to SDM-X in the first set 712 and/or any of the devices T1-TY in the second set 714. Further, in at least one embodiment, the switching circuitry 710 may allow any of the devices T1-TY in the second set 714 to communicate with any of the devices T1-TY in the second set 714 and/or any of the devices SD1-1 to SDM-X in the first set 712.

The switching circuitry 710 may include a number “N” of outbound switches OSW1-OSWN, a predetermined number “M*N” of internal switches IS1C1-ISMCN, signal conductors 716, and a route block 718 that controls the operations of the internal switches IS1C1-ISMCN. The route block 718 has been illustrated as including hardware 720 that may include at least one processor 722, memory 724, and one or more counters 726. In at least one embodiment, each of the processor(s) 722 may be implemented as one or more hardware state machines, one or more microprocessors, one or more microcontrollers, one or more controllers, or the like. The memory 724 (e.g., one or more non-transitory processor-readable medium) may be implemented, for example, using volatile memory (e.g., dynamic random-access memory (“DRAM”)) and/or nonvolatile memory (e.g., a hard drive, a solid state device (“SSD”), and/or the like).

The signal conductors 716 interconnect the first set 712, the second set 714, the internal switches IS1C1-ISMCN, and the outbound switches OSW1-OSWN. In the example illustrated, the signal conductors 716 may include any number of signal conductors. The signal conductors 716 may each be implemented as a wire, a trace, and/or any other type of electrical conductor. As a non-limiting example, one or more of the signal conductors 716 may each be implemented as a wire-based serial near-range communications link. By way of another non-limiting example, one or more of the signal conductors 716 may each be implemented as a Scalable Link Interface (“SLI”).

In the embodiment illustrated, the signal conductors 716 include signal conductors 734, 740, and 742. The signal conductors 734 connect the devices SD1-1 to SDM-X to the internal switches IS1C1-ISMCN. For ease of illustration, only those of the signal conductors 734 that connect each of the devices SD1-1 to SD1-X to the internal switches IS1C1-IS1CN have been illustrated in FIG. 7. In at least one embodiment, the internal switches IS1C1-IS1CN may each include a different port that is connected to each of at least a portion of the devices SD1-1 to SDM-X (e.g., the devices SD1-1 to SD1-X, respectively) by the signal conductors 734. Similarly, the internal switches IS2C1-IS2CN may each include a different internal port that is connected to each of at least a portion of the devices SD1-1 to SDM-X (e.g., the devices SD2-1 to SD2-X, respectively) by the signal conductors 734. Further, the internal switches ISMC1-ISMCN may each include a different internal port that is connected to each of at least a portion of the devices SD1-1 to SDM-X (e.g., the devices SDM-1 to SDM-X, respectively) by the signal conductors 734.

The signal conductors 742 connect the internal switches IS1C1-ISMCN to the outbound switches OSW1-OSWN. For example, at least one of the signal conductors 742 connects each of the internal switches IS1C1-ISMC1 to the outbound switch OSW1, at least one of the signal conductors 742 connects each of the internal switches IS1C2-ISMC2 to the outbound switch OSW2, and at least one of the signal conductors 742 connects each of the internal switches IS1CN-ISMCN to the outbound switch OSWN.

The signal conductors 740 connect the outbound switches OSW1-OSWN to the devices T1-TY. The outbound switches OSW1-OSWN may each include a different port that is connected by at least one of signal conductors 740 to at least one of the devices T1-TY.

While the switching circuitry 710 has been illustrated as including the internal switches IS1C1-ISMCN, the switching circuitry 710 may include any number of internal switches including a single internal switch. Further, the internal switches IS1C1-ISMCN have been illustrated as being arranged in a two-dimensional array that includes the number “M” of rows and the number “N” of columns. However, this is not a requirement and the internal switches IS1C1-ISMCN may positioned in alternate arrangements to implement any network topology, including a three-dimensional array. One or more of the internal switches IS1C1-ISMCN may be coupled to one another. For example, from the perspective of one of the internal switches IS1C1-ISMCN, one or more of the other internal switches IS1C1-ISMCN may be one of the devices T1-TY. Further, the switching circuitry 710 may be coupled to one or more switches (e.g., switching circuitry like the switching circuitry 710) that is/are external to the switching circuitry 710. For example, one or more of the devices SD1-1 to SDM-X and/or the devices T1-TY may each be implemented as an external switch.

The route block 718 may be connected to each of the internal switches IS1C1-ISMCN and/or each of at least a portion of the signal conductors 716 by one or more buses. For example, the processor(s) 722 and the memory 724 may be connected to one another by one or more buses 728. The bus(es) 728 may also connect the processor(s) 722 and the memory 724 to the internal switches IS1C1-ISMCN and/or each of at least a portion of the signal conductors 716. The memory 724 (e.g., a non-transitory processor readable media) stores instructions 730 that are executable by the processor(s) 722, data 732, and firmware 752, which may perform monitoring and data manipulation functions. For example, the firmware 752 may instruct the hardware 720 to transition one or more of the signal conductors 716, from the active state to the inactive state and vice versa.

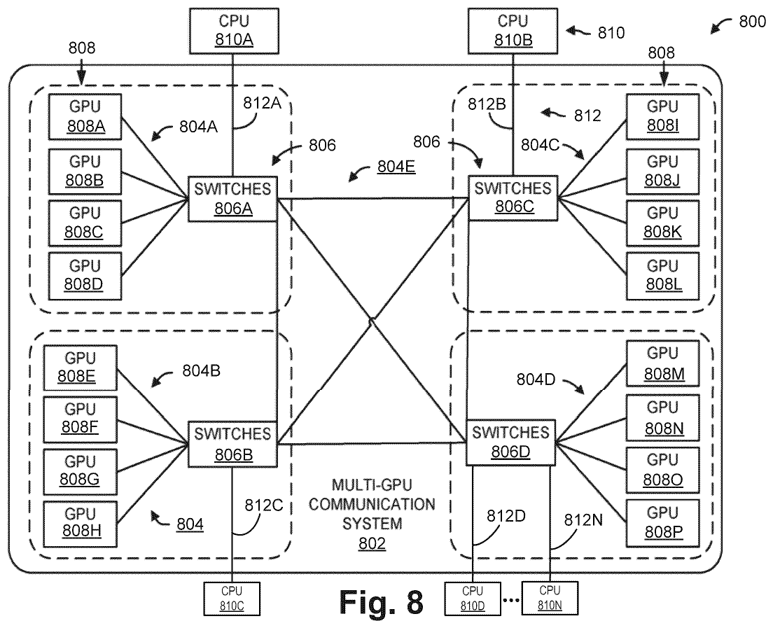

FIG. 8 illustrates a block diagram of an example system 800, in accordance with at least one embodiment. The system 800 may include, in at least one embodiment, one or more CPUs 810 connected to one or more multi-GPU communication systems (e.g., a multi-GPU communication system 802) by one or more signal conductors 812. In the embodiment illustrated in FIG. 8, the CPU(s) 810 include CPUs 810A, 810B, 810C, and 810D, which are connected to the multi-GPU communication system 802 by signal conductors 812A, 812B, 812C, and 812D, respectively. In some aspects, zero, one, or more CPUs (e.g., 810N) may be in communication with a switch (e.g., 806D) via one or more signal conductors 812N). In FIG. 8, the multi-GPU communication system 802 includes GPUs 808 connected to one another by at least one switch 806 and at least one signal conductor 804. In the embodiment illustrated, the switch(es) 806 include switches 806A-806D, the GPUs 808 include GPUs 808A-208P, and the signal conductor(s) 804 include signal conductors 804A-204E.

The system 800 may be characterized as being an example implementation of the system 700 (see FIG. 7). For example, the CPU(s) 810 and/or the GPUs 808 may be implementations of the set 712 and/or the set 714. In at least one embodiment, the CPU(s) 810 may be substantially identical to the devices SD1-1 to SDM-X and/or the devices T1-TY. In at least one embodiment, the GPUs 808 may be substantially identical to the devices SD1-1 to SDM-X and/or the devices T1-TY. By way of another non-limiting example, the signal conductor(s) 804 and/or the signal conductor(s) 812 may be implementations of the signal conductors 716. In at least one embodiment, the signal conductor(s) 804 and/or the signal conductor(s) 812 may be substantially identical to the signal conductors 716. By way of yet another non-limiting example, the switch(es) 806 may be implementations of the internal switches IS1C1-ISMCN and/or the outbound switches OSW1-OSWN. In at least one embodiment, the switch(es) 806 may be substantially identical to the switches IS1C1-ISMCN (see FIG. 7) and/or the outbound switches OSW1-OSWN.

As a non-limiting example, the signal conductors 804 may link the GPUs 808 to the switch(es) 806, and the signal conductors 812A and 812B may link the at least one of the switch(es) 806 to one or more of the CPU(s) 810. As illustrated in FIG. 8, the CPUs 810A and 810B may connected to the switches 806A and 806C, respectively, by the signal conductors 812A and 812B, respectively. In at least one embodiment, one or more of the CPU(s) 810 may be implemented as a CPU 1600 illustrated in FIG. 16. One or more of the GPUs 808 may be implemented as one or more parallel processor(s) 1412 illustrated in FIG. 14.

The multi-GPU communication system 802 may implement a form of mesh networking, which may have a local area network topology in which infrastructure nodes or devices may be connected directly, dynamically, and non-hierarchically to other nodes and may cooperate with one another to efficiently route data. Examples of infrastructure devices may include bridges, the switch(es) 806, and/or other types of infrastructure devices. The multi-GPU communication system 802 may be referred to as a GPU-to-GPU System. By way of a non-limiting example, the multi-GPU communication system 802 may be implemented as a GPU-to-GPU link system (e.g., a NVLINK® GPU-to-GPU interconnect system) in which the switch(es) 806 may include one or more GPU-to-GPU switches (e.g., one or more NVSWITCH™ switches).

The switch 806A is connected to the GPUs 808A-208D by the signal conductors 804A, the switch 806B is connected to the GPUs 808E-808H by the signal conductors 804B, the switch 806C is connected to the GPUs 808I-808L by the signal conductors 804C, and the switch 806D is connected to the GPUs 808M-808P by the signal conductors 804D. The switches 806A-806D are connected to one another by signal conductors 804E. Each of the switch(es) 806 may act as a router and/or a connection between two endpoints within the system 800 for the duration of a dedicated connection. In at least one embodiment, one or more of the switch(es) 806 may be implemented using an on-node switch architecture (e.g., one or more NVSWITCH™ switches) that connects processing units (e.g., one or more GPUs, one or more CPUs, and/or one or more other types of processor) together. The system 800 may function as part of another system, such as a data center, which incorporates hardware, networking, software, and/or libraries, and executes applications, such applications perform inferences, for example by executing Artificial Intelligence (“AI”) or machine learning models.

The systems and methods described herein may be used by, without limitation, non-autonomous vehicles, semi-autonomous vehicles (e.g., in one or more adaptive driver assistance systems (ADAS)), piloted and un-piloted robots or robotic platforms, warehouse vehicles, off-road vehicles, vehicles coupled to one or more trailers, flying vessels, boats, shuttles, emergency response vehicles, motorcycles, electric or motorized bicycles, aircraft, construction vehicles, underwater craft, drones, and/or other vehicle types. The systems and methods described herein may be used in augmented reality, virtual reality, mixed reality, robotics, security and surveillance, autonomous or semi-autonomous machine applications, and/or any other technology spaces in which one or more signal conductors may have at least two different states that consume different amounts of power.

The systems and methods described herein may be used by, without limitation, non-autonomous vehicles, semi-autonomous vehicles (e.g., in one or more adaptive driver assistance systems (ADAS)), piloted and un-piloted robots or robotic platforms, warehouse vehicles, off-road vehicles, vehicles coupled to one or more trailers, flying vessels, boats, shuttles, emergency response vehicles, motorcycles, electric or motorized bicycles, aircraft, construction vehicles, underwater craft, drones, and/or other vehicle types. Further, the systems and methods described herein may be used for a variety of purposes, by way of example and without limitation, for machine control, machine locomotion, machine driving, synthetic data generation, model training, perception, augmented reality, virtual reality, mixed reality, robotics, security and surveillance, simulation and digital twinning, autonomous or semi-autonomous machine applications, deep learning, environment simulation, object or actor simulation and/or digital twinning, data center processing, conversational AI, light transport simulation (e.g., ray-tracing, path tracing, etc.), collaborative content creation for 3D assets, cloud computing, web-hosted services or web-hosted platforms, and/or any other suitable applications.

Disclosed embodiments may be comprised in a variety of different systems such as automotive systems (e.g., a control system for an autonomous or semi-autonomous machine, a perception system for an autonomous or semi-autonomous machine), systems implemented using a robot, aerial systems, medial systems, boating systems, smart area monitoring systems, systems for performing deep learning operations, systems for performing simulation operations, systems for performing digital twin operations, systems implemented using an edge device, systems incorporating one or more virtual machines (VMs), systems for performing synthetic data generation operations, systems implemented at least partially in a data center, systems for performing conversational AI operations, systems for performing light transport simulation, systems for performing collaborative content creation for 3D assets, systems implemented at least partially using cloud computing resources, systems for implementing web-hosted services (e.g., for program optimization at runtime) or web-hosted platforms (e.g., integrated development environments that include program optimization as a service), as an application programming interface (“API”) between two or more separate applications or systems, and/or other types of systems.

### Data Center

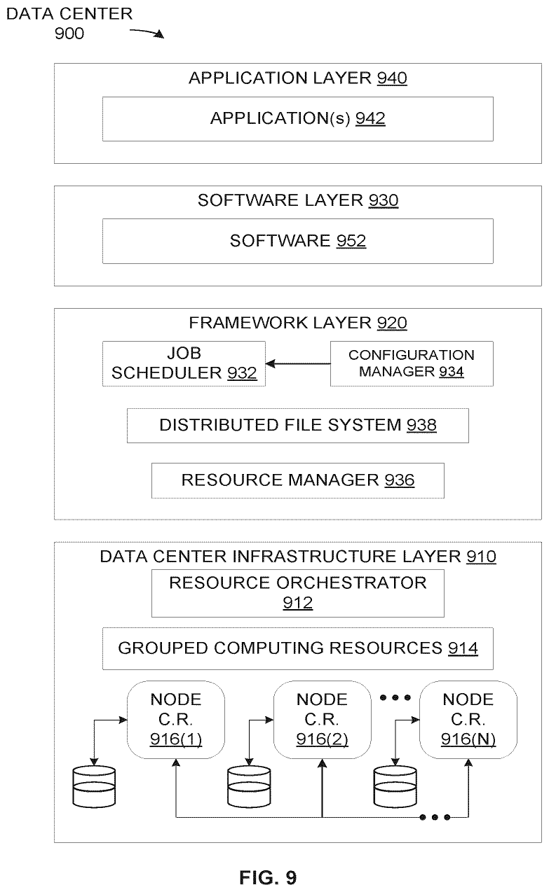

FIG. 9 illustrates an example data center 900, in accordance with at least one embodiment. In at least one embodiment, data center 900 includes, without limitation, a data center infrastructure layer 910, a framework layer 920, a software layer 930 and an application layer 940.

In at least one embodiment, as shown in FIG. 9, data center infrastructure layer 910 may include a resource orchestrator 912, grouped computing resources 914, and node computing resources (“node C.R.s”) 916(1)-916(N), where “N” represents any whole, positive integer. In at least one embodiment, node C.R.s 916(1)-916(N) may include, but are not limited to, any number of central processing units (“CPUs”) or other processors (including accelerators, field programmable gate arrays (“FPGAs”), data processing units (“DPUs”) in network devices, graphics processors, etc.), memory devices (e.g., dynamic read-only memory), storage devices (e.g., solid state or disk drives), network input/output (“NW I/O”) devices, network switches, virtual machines (“VMs”), power modules, and cooling modules, etc. In at least one embodiment, one or more node C.R.s from among node C.R.s 916(1)-916(N) may be a server having one or more of above-mentioned computing resources.

In at least one embodiment, grouped computing resources 914 may include separate groupings of node C.R.s housed within one or more racks (not shown), or many racks housed in data centers at various geographical locations (also not shown). Separate groupings of node C.R.s within grouped computing resources 914 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 912 may configure or otherwise control one or more node C.R.s 916(1)-916(N) and/or grouped computing resources 914. In at least one embodiment, resource orchestrator 912 may include a software design infrastructure (“SDI”) management entity for data center 900. In at least one embodiment, resource orchestrator 912 may include hardware, software or some combination thereof.

In at least one embodiment, as shown in FIG. 9, framework layer 920 includes, without limitation, a job scheduler 932, a configuration manager 934, a resource manager 936 and a distributed file system 938. In at least one embodiment, framework layer 920 may include a framework to support software 952 of software layer 930 and/or one or more application(s) 942 of application layer 940. In at least one embodiment, software 952 or application(s) 942 may respectively include web-based service software or applications, such as those provided by Amazon Web Services, Google Cloud and Microsoft Azure. In at least one embodiment, framework layer 920 may be, but is not limited to, a type of free and open-source software web application framework such as Apache Spark™ (hereinafter “Spark”) that may utilize distributed file system 938 for large-scale data processing (e.g., “big data”). In at least one embodiment, job scheduler 932 may include a Spark driver to facilitate scheduling of workloads supported by various layers of data center 900. In at least one embodiment, configuration manager 934 may be capable of configuring different layers such as software layer 930 and framework layer 920, including Spark and distributed file system 938 for supporting large-scale data processing. In at least one embodiment, resource manager 936 may be capable of managing clustered or grouped computing resources mapped to or allocated for support of distributed file system 938 and job scheduler 932. In at least one embodiment, clustered or grouped computing resources may include grouped computing resource 914 at data center infrastructure layer 910. In at least one embodiment, resource manager 936 may coordinate with resource orchestrator 912 to manage these mapped or allocated computing resources.

In at least one embodiment, software 952 included in software layer 930 may include software used by at least portions of node C.R.s 916(1)-916(N), grouped computing resources 914, and/or distributed file system 938 of framework layer 920. One or more types of software may include, but are not limited to, Internet web page search software, e-mail virus scan software, database software, and streaming video content software.

In at least one embodiment, application(s) 942 included in application layer 940 may include one or more types of applications used by at least portions of node C.R.s 916(1)-916(N), grouped computing resources 914, and/or distributed file system 938 of framework layer 920. In at least one or more types of applications may include, without limitation, CUDA applications.

In at least one embodiment, any of configuration manager 934, resource manager 936, and resource orchestrator 912 may implement any number and type of self-modifying actions based on any amount and type of data acquired in any technically feasible fashion. In at least one embodiment, self-modifying actions may relieve a data center operator of data center 900 from making possibly bad configuration decisions and possibly avoiding underutilized and/or poor performing portions of a data center.

In at least one embodiment, the data center 900 may be used to implement the system 700 (see FIG. 7) and/or the system 800 (see FIG. 8). For example, the first set 712 and/or the second set 714 may include one or more of the grouped computing resources 914 and/or one or more of the C.R.s 916(1)-916(N). In at least one embodiment, one or more systems depicted in FIG. 9 are utilized to implement one or more systems and/or processes such as those described in connection with FIGS. 1-8.

In at least one embodiment, one or more components of systems and/or processors disclosed above can communicate with one or more CPUs, ASICs, GPUs, FPGAs, or other hardware, circuitry, or integrated circuit components that include, e.g., an upscaler or upsampler to upscale an image, an image blender or image blender component to blend, mix, or add images together, a sampler to sample an image (e.g., as part of a DSP), a neural network circuit that is configured to perform an upscaler to upscale an image (e.g., from a low resolution image to a high resolution image), or other hardware to modify or generate an image, frame, or video to adjust its resolution, size, or pixels; one or more components of systems and/or processors disclosed above can use components described in this disclosure to perform methods, operations, or instructions that generate or modify an image.

It is to be appreciated that any feature described herein can be claimed in combination with any other feature(s) as described herein, regardless of whether the features come from the same described embodiment.

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art. It is to be appreciated that any feature described herein can be claimed in combination with any other feature(s) as described herein, regardless of whether the features come from the same described embodiment.

What is claimed is:

1. An apparatus comprising:
one or more memory devices to store data describing a plurality of computing components and one or more wireless connectivity requirements for a data center; and
one or more processors, coupled to the one or more memory devices, to:
determine a physical layout for the plurality of computing components based at least on the one or more wireless connectivity requirements and a computing component density within the data center; and
generate a floor plan for the data center based on the physical layout.

2. The apparatus of claim 1, wherein the plurality of computing components comprises at least one of a server, a tray, a rack, a pod, switch, or a cluster.

3. The apparatus of claim 2, wherein the physical layout is determined based on a wireless connectivity architecture independent of cable routing paths.

4. The apparatus of claim 1, wherein the one or more processors are further to:
obtain a measure of wireless communication parameter between the plurality of computing components; and
determine a placement of one or more computing components of the plurality of computing components based on the measure of the wireless communication parameter.

5. The apparatus of claim 1, wherein the one or more processors are further to: position the plurality of computing components within the floor plan based on a threshold associated with a wireless communication parameter for one or more communicating components of the plurality of computing components.

6. The apparatus of claim 5, wherein the threshold associated with the wireless communication parameter includes at least one wireless propagation characteristic comprising at least one of: signal frequency, bandwidth, modulation scheme, signal strength, data rate, latency, bit error rate, or signal interference.

7. The apparatus of claim 1, wherein the one or more processors are further to: adjust the physical layout based on a cooling requirement of one or more computing components of the plurality of computing components within the data center.

8. The apparatus of claim 1, wherein the one or more processors are further to: modify the physical layout based on a power delivery requirement of one or more computing components of the plurality of computing components within the data center.

9. The apparatus of claim 1, wherein the floor plan indicates positions of the plurality of computing components and corresponding wireless connectivity paths between the plurality of computing components.

10. The apparatus of claim 1, wherein the one or more processors are further to: transmit a configuration to at least one wireless communication device to configure a wireless connectivity path between a pair of computing components of the plurality of computing components.

11. The apparatus of claim 1, wherein the one or more processors are further to: reconfigure physical positions of one or more computing components of the plurality of computing components in response to changes in wireless communication performance.

12. The apparatus of claim 1, wherein the one or more processors are further to:
input data describing the plurality of computing components within the data center and the one or more wireless connectivity requirements into a machine-learning model trained to generate data center floor plans, and
obtain, from the machine-learning model, the floor plan for the data center.

13. The apparatus of claim 1, wherein the one or more processors are further configured to dynamically adjust the physical layout to scale a number of computing components within the data center based on at least one of a modified computing requirements or modified wireless connectivity requirements, without adding wired infrastructure.

14. The apparatus of claim 1, wherein the one or more processors are further configured to determine and configure wireless connectivity paths in response to at least one of an incremental increase or incremental decrease in a number of computing components.

15. A machine-readable medium having data stored thereon, which when executed by one or more processors, cause the one or more processors to:
receive data describing a plurality of computing components and one or more wireless connectivity requirements for a data center;
determine a physical layout for the plurality of computing components based at least on the one or more wireless connectivity requirements and a computing component density within the data center; and
generate a floor plan for the data center based on the physical layout.

16. The machine-readable medium of claim 15, wherein the plurality of computing components comprises at least one of a server, a tray, a rack, a pod, or a cluster.

17. The machine-readable medium of claim 16, wherein the physical layout is determined based on a wireless connectivity architecture independent of cable routing paths.

18. The machine-readable medium of claim 15, wherein the one or more processors are to: adjust the physical layout based on a cooling requirement of one or more computing components of the plurality of computing components within the data center and a power delivery requirement of one or more computing components of the plurality of computing components within the data center.

19. An apparatus comprising:
one or more memory devices to store a wireless communication performance threshold; and
one or more processors, coupled to the one or more memory devices, to:
monitor wireless communication performance metrics between a plurality of computing components within a data center arranged according to an initial floor plan;
detect a change in at least one of the wireless communication performance metrics that exceeds the wireless communication performance threshold;
identify one or more computing components associated with the detected change; and
determine a modified physical arrangement for the identified one or more computing components based on the wireless communication performance metrics.

20. The apparatus of claim 19, wherein the wireless communication performance metrics comprise at least one of signal strength, data throughput, latency, bit error rate, packet loss, signal-to-noise ratio, or channel quality indicator.

21. The apparatus of claim 19, wherein the one or more processors are to:
generate instructions for physically relocating the identified one or more computing components according to the modified physical arrangement; and
transmit the instructions to a data center management system for implementation.

22. The apparatus of claim 19, wherein the one or more processors are to:
determine a temporary wireless communication path to maintain network connectivity during physical relocation of the identified one or more computing components;
configure one or more wireless communication devices to implement the temporary wireless communication path; and
after physical relocation of the identified one or more computing components, configure the one or more wireless communication devices to implement a permanent wireless communication path according to the modified physical arrangement.
